(19) United States
(12) Patent Application Publication
(10) Pub. No.: US 2026/0304940 A1
(43) Pub. Date: Oct. 1, 2026

(54) SEMICONDUCTOR DEVICE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jyun-Yang SHEN, Kaohsiung City (TW); Chih-Hao CHANG, Chu-Bei City, Hsin-Chu (TW); Jhon-Jhy LIAW, Zhudong Township, Hsinchu County (TW); Yu-Hsuan LU, Kaohsiung City (TW)

(73) Assignee: TAIWAN SEMICONDUCTOR MANUFACTURING COMPANY, LTD., Hsinchu (TW)

(21) Appl. No.: 19/092,117

(22) Filed: Mar. 27, 2025

(51) Int. Cl. H10D 84/85; H10D 30/00; H10D 30/01; H10D 30/43; H10D 62/10; H10D 62/13; H10D 62/60; H10D 62/832; H10D 62/834; H10D 64/66; H10D 84/01

(52) U.S. Cl. CPC H10D 84/851; H10D 30/014; H10D 30/0191; H10D 30/43; H10D 30/502; H10D 62/102; H10D 62/121; H10D 62/151; H10D 62/60; H10D 62/832; H10D 62/834; H10D 64/665; H10D 64/667; H10D 84/017; H10D 84/856

(57) ABSTRACT

A semiconductor device structure includes nanostructures formed over a substrate. The structure also includes a gate structure wrapped around the nanostructures. The structure also includes inner spacers formed over opposite sides of the gate structure. Each of the inner spacers includes a top surface, a bottom surface, and a sidewall connecting the top surface and the bottom surface. The structure also includes interposing structures formed over sidewalls of the nanostructures. The structure also includes a source/drain epitaxial structure formed over the interposing structures. The interposing structures and the source/drain epitaxial structures have different compositions, and the interposing structure covers the sidewall of at least one of the inner spacers.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, the integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1F are perspective representations of various stages of forming a semiconductor device structure, in accordance with some embodiments of the disclosure.

FIGS. 1G, 1G-1, 1H-1I, 1I-1 are cross-sectional representations of various stages of forming a semiconductor device structure, in accordance with some embodiments of the disclosure.

FIGS. 2A-2B are cross-sectional representations of various stages of forming a semiconductor device structure, in accordance with some embodiments of the disclosure.

FIGS. 3A, 3A-1, 3B, 3B-1 are cross-sectional representations of various stages of forming a semiconductor device structure, in accordance with some embodiments of the disclosure.

FIGS. 4A-4B are cross-sectional representations of various stages of forming a semiconductor device structure, in accordance with some embodiments of the disclosure.

FIGS. 5A-5B are cross-sectional representations of various stages of forming a semiconductor device structure, in accordance with some embodiments of the disclosure.

FIGS. 6A-6B are cross-sectional representations of various stages of forming a semiconductor device structure, in accordance with some embodiments of the disclosure.

FIGS. 7A-7B are cross-sectional representations of various stages of forming a semiconductor device structure, in accordance with some embodiments of the disclosure.

FIGS. 8A-8B are cross-sectional representations of various stages of forming a semiconductor device structure, in accordance with some embodiments of the disclosure.

FIGS. 9A-9B are cross-sectional representations of various stages of forming a semiconductor device structure, in accordance with some embodiments of the disclosure.

FIGS. 10A-10B are cross-sectional representations of various stages of forming a semiconductor device structure, in accordance with some embodiments of the disclosure.

FIGS. 11A-11B are cross-sectional representations of various stages of forming a semiconductor device structure, in accordance with some embodiments of the disclosure.

FIGS. 12A-12B are cross-sectional representations of various stages of forming a semiconductor device structure, in accordance with some embodiments of the disclosure.

FIGS. 13A-13B are cross-sectional representations of various stages of forming a semiconductor device structure, in accordance with some embodiments of the disclosure.

FIGS. 14A-14B are cross-sectional representations of various stages of forming a semiconductor device structure, in accordance with some embodiments of the disclosure.

FIGS. 15A-15B are cross-sectional representations of various stages of forming a semiconductor device structure, in accordance with some embodiments of the disclosure.

FIGS. 16A-16B are cross-sectional representations of various stages of forming a semiconductor device structure, in accordance with some embodiments of the disclosure.

FIGS. 17A-17B are cross-sectional representations of various stages of forming a semiconductor device structure, in accordance with some embodiments of the disclosure.

FIGS. 18A-18B are cross-sectional representations of various stages of forming a semiconductor device structure, in accordance with some embodiments of the disclosure.

FIGS. 19A-19B are cross-sectional representations of various stages of forming a semiconductor device structure, in accordance with some embodiments of the disclosure.

FIGS. 20A-20B are cross-sectional representations of various stages of forming a semiconductor device structure, in accordance with some embodiments of the disclosure.

FIGS. 21A-21B are cross-sectional representations of various stages of forming a semiconductor device structure, in accordance with some embodiments of the disclosure

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, forksheet structures, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments for forming a semiconductor device structure are provided. The method for forming the semiconductor device structure may include forming an interposing structure between the channel layer and the source/drain structure. The interposing structure vertically protrudes beyond the channel layer, and the interposing structure and the source/drain structure have different compositions. The interposing structure may be resistant when forming the gate structure, therefore, the source/drain structure may not be damaged. The leakage current between the gate and the contacts may be reduced. The interposing structure may also prevent dopant diffusion from the source/drain structure.

The semiconductor device structure may include various active devices. For example, the semiconductor device structure may include gate all around (GAA) structures. The semiconductor device structure may also include channel structures such as nanosheet structures, nanowire structures, forksheet structures, and CFET structures. The semiconductor device structure may also include FinFET structures, or Si and SiGe planar transistors. A back-side contact structure may also be applied to the semiconductor device.

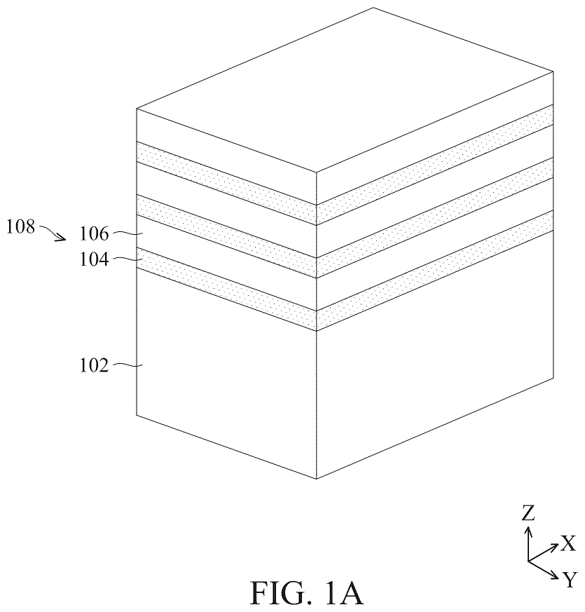

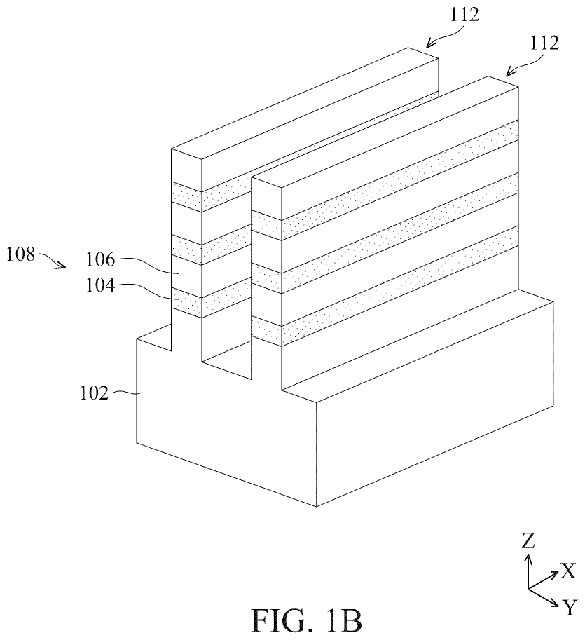

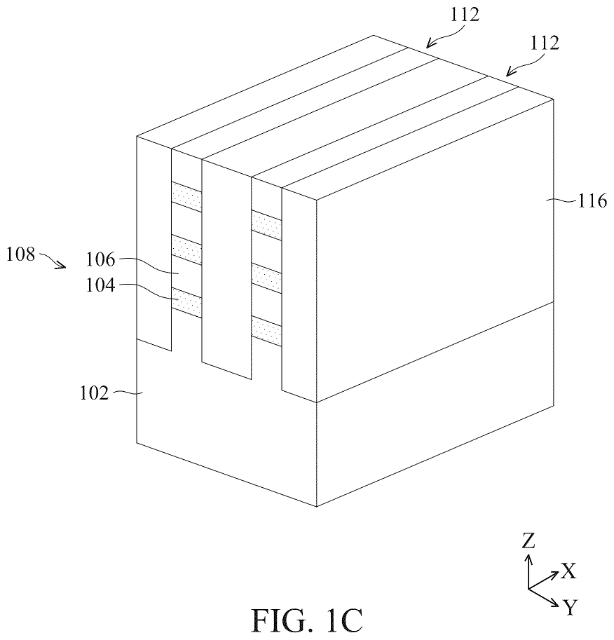

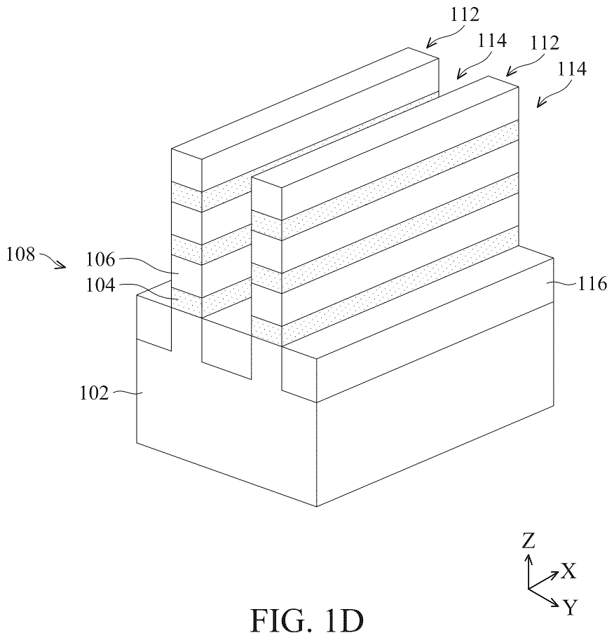

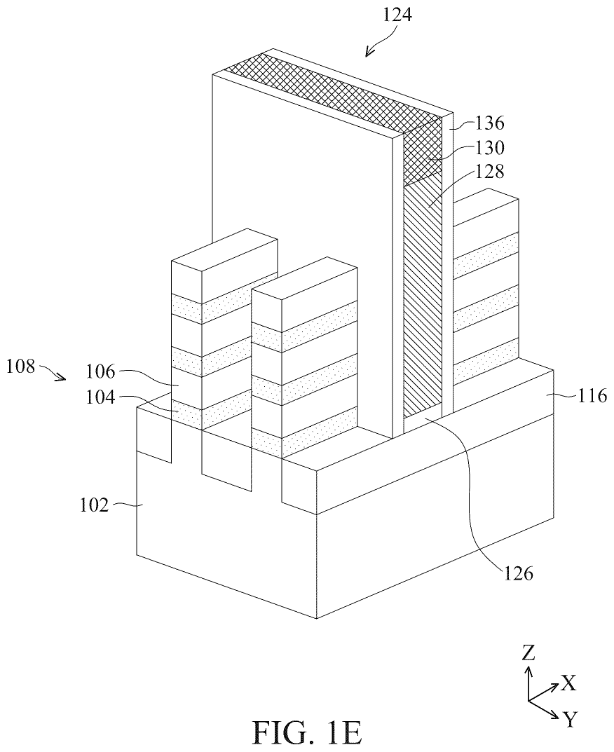

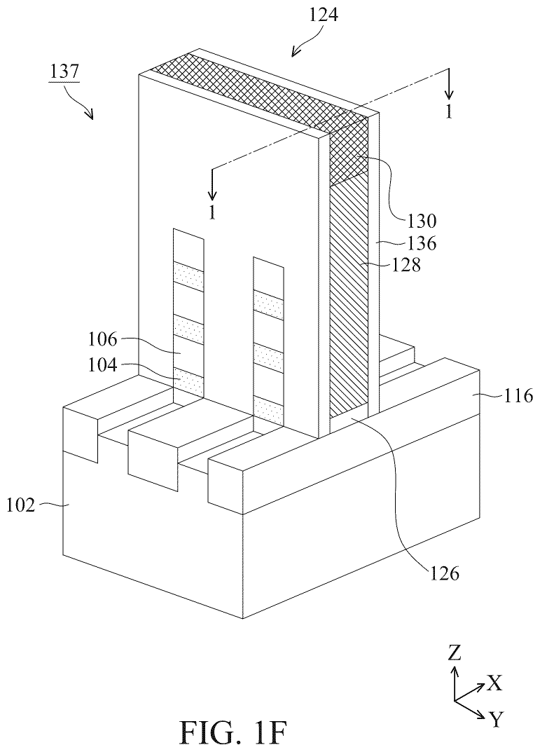

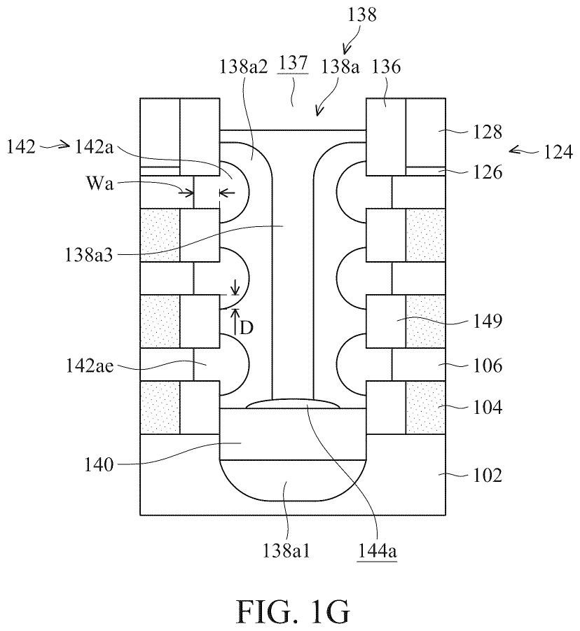

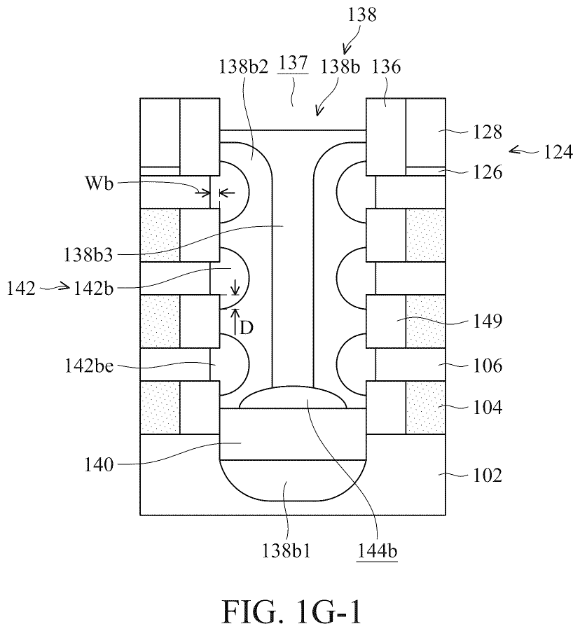

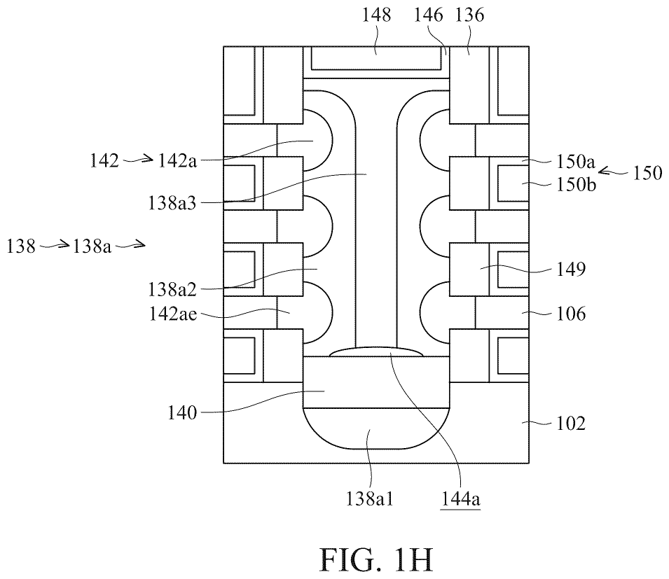

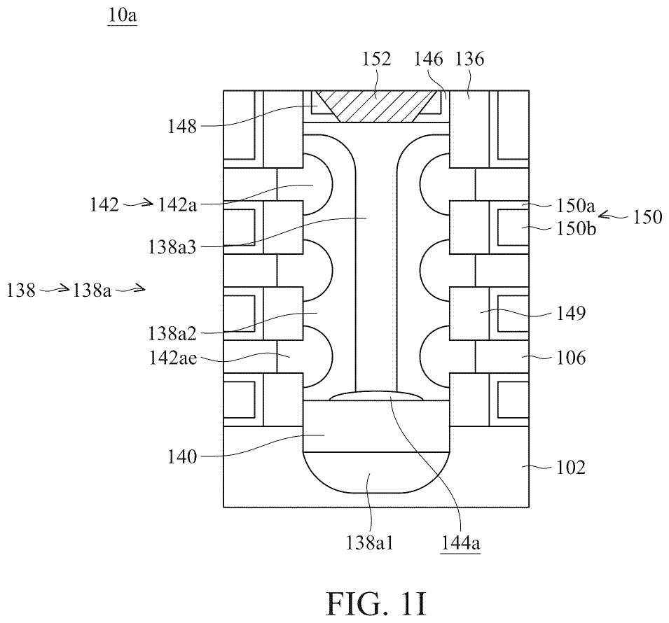

The semiconductor device structure 10a may be a nanostructure transistor. FIGS. 1A-1F are perspective representations of various stages of forming a semiconductor device structure 10a, in accordance with some embodiments of the disclosure. FIGS. 1G, 1G-1, 1H-1I are cross-sectional representations of various stages of forming a semiconductor device structure 10a, in accordance with some embodiments of the disclosure. FIGS. 1G, 1G-1, 1H-1I show cross-sectional representations taken along line 1-1 in FIG. 1F.

A semiconductor stack 108 including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, alloy semiconductor materials, or a combination thereof. Examples of the elementary semiconductor materials may include, but are not limited to, crystal silicon, polycrystalline silicon, amorphous silicon, germanium, diamond, or a combination thereof. Examples of the compound semiconductor materials may include, but are not limited to, silicon carbide, gallium nitride, gallium arsenic, gallium phosphide, indium phosphide, indium arsenide, indium antimonide, or a combination thereof. Examples of the alloy semiconductor materials may include, but are not limited to, SiGe, GaAsP, AlInAs, AlGaAs, GaInAs, GaInP, GaInAsP, or a combination thereof. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are alternating stacked over the substrate 102 to form the semiconductor stack 108, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are three layers of the first semiconductor material layers 104 and three layers of the second semiconductor material layers 106 shown in FIG. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure may be formed over the semiconductor stack 108. The mask structure may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

After the first semiconductor material layers 104 and the second semiconductor material layers 106 are formed as the semiconductor stack 108 over the substrate 102, the semiconductor stack 108 is patterned to form fin structures 112 using the mask structure as a mask layer, as shown in FIG. 1B in accordance with some embodiments. The fin structures 112 may include base fin structures and the semiconductor stack 108, including the first semiconductor material layers 104 and the second semiconductor material layers 106, formed over the base fin structure.

The patterning process may include forming a mask structure over the first semiconductor material layers 104 and the second semiconductor material layers 106 and etching the semiconductor stack 108 and the underlying substrate 102 through the mask structure.

The patterning process of forming the fin structures 112 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 112 are formed, a liner layer may be formed over the fin structures 112 and in the trenches between the fin structures 112. The liner layer may be conformally formed over the substrate 102, the fin structures 112, and the mask structure covering the fin structures 112. A liner layer may be used to protect the fin structures 112 from being damaged in the following processes (such as an anneal process or an etching process). The liner layer may be made of silicon nitride. The liner layer may be formed using thermal oxidation, a CVD process, an atomic layer deposition (ALD) process, an LPCVD process, a plasma enhanced CVD (PECVD) process, an HDPCVD process, a flowable CVD (FCVD) process, another applicable process, or a combination thereof.

Next, an isolation material 116 is then filled into the trenches between the fin structures 112 and over the liner layer, as shown in FIG. 1C in accordance with some embodiments. The isolation material 116 may be made of silicon oxide, silicon nitride, silicon oxynitride (SiON), fluoride-doped silicate glass (FSG), other low-k dielectric materials, or a combination thereof. The isolation material 116 may be deposited by a deposition process, such as a chemical vapor deposition (CVD) process (e.g. a flowable CVD (FCVD) process), a spin-on-glass process, or another applicable process.

Next, the hard mask layer over the fin structures 112 may be removed, and the pad layer over the fin structures 112 may be exposed. The hard mask layer may be removed by performing a planarization process such as a chemical mechanical polishing (CMP) process.

Next, the isolation material 116 is etched back using an etching process, and an isolation structure 116 is formed surrounding the base fin structure, as shown in FIG. 1D in accordance with some embodiments. The etching process may be used to remove the top portion of the isolation material 116. The pad layer over the fin structure 112 may be removed in the etching process. As a result, the semiconductor stack 108 may be exposed. The isolation structure 116 may be a shallow trench isolation (STI) structure 116. The isolation structure 116 may be configured to electrically isolate active regions such as fin structures 112 of the semiconductor structure 10a and prevent electrical interference and crosstalk.

Next, a dummy gate structure 124 is formed over and across the fin structures 112, as shown in FIG. 1E in accordance with some embodiments. The dummy gate structure 124 may be used to define the source/drain regions and the channel regions of the resulting semiconductor structure 10a. The dummy gate structure 124 may include a dummy gate dielectric layer 126 and a dummy gate electrode layer 128. The dummy gate dielectric layer 126 and the dummy gate electrode layer 128 may be replaced by the following steps to form a real gate structure with a high-k dielectric layer and a metal gate electrode layer.

The dummy gate dielectric layer 126 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 126 may be formed by an oxidation process (e.g., a dry oxidation process, or a wet oxidation process), a chemical vapor deposition process, other applicable processes, or a combination thereof. Alternatively, the dummy gate dielectric layer 126 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 128 may include polycrystalline-silicon (poly-Si), poly-crystalline silicon-germanium (poly-SiGe), other applicable materials, or a combination thereof. The dummy gate electrode layer 128 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Next, a hard mask layer 130 is formed over the dummy gate structure 124, as shown in FIG. 1E in accordance with some embodiments. The hard mask layer 130 may include multiple layers, such as an oxide layer and a nitride layer. In some embodiments, the oxide layer includes silicon oxide, and the nitride layer includes silicon nitride.

The formation of the dummy gate structure 124 may include conformally forming a dielectric material as the dummy gate dielectric layer 126. Afterwards, a conductive material may be formed over the dielectric material as the dummy gate electrode layer 128. The hard mask layer 130, including the oxide layer and the nitride layer, may be formed over the conductive material. Next, the dielectric material and the conductive material may be patterned and etched through the hard mask layer 130 to form the dummy gate structure 124, as shown in FIG. 1E in accordance with some embodiments. The dummy gate dielectric layer 126 and the dummy gate electrode layer 128 may be etched by a dry etching process. After the etching process, the first semiconductor material layers 104 and the second semiconductor material layers 106 may be exposed at opposite sides of the dummy gate structure 124.

Next, a conformal dielectric layer is formed over the substrate 102 and the dummy gate structure 124, and then an etching process is performed. A pair of gate spacer layers 136 is formed over opposite sidewalls of the dummy gate structure 124, as shown in FIG. 1E in accordance with some embodiments

The gate spacer layers 136 may be multi-layer structures formed by different materials with different etching selectivity. The gate spacer layers 136 may be made of silicon oxide, silicon nitride, silicon oxynitride, dielectric materials, or a combination thereof. The gate spacer layers 136 may be formed by a chemical vapor deposition (CVD) process, a spin-on-glass process, or another applicable process.

After the gate spacer layers 136 are formed, the first semiconductor material layers 104 and the second semiconductor material layers 106 of the fin structures 112 not covered by the dummy gate structure 124 and the gate spacer layers 136 are etched to form the source/drain opening 137 beside the dummy gate structure 124, as shown in FIG. 1F in accordance with some embodiments. A recess may be formed in the isolation structure 116 when etching the first semiconductor material layers 104 and the second semiconductor material layers 106 of the fin structures 112.

The fin structures 112 may be recessed by performing a number of etching processes. That is, the first semiconductor material layers 104 and the second semiconductor material layers 106 of the fin structures 112 may be etched in different etching processes. The etching process may be a dry etching process or a wet etching process. The fin structures 112 may be etched by a dry etching process.

Next, the first semiconductor material layers 104 may be laterally etched from the source/drain opening 137 to form first recesses. The outer portions of the first semiconductor material layers 104 may be removed, and the inner portions of the first semiconductor material layers 104 under the dummy gate structure 124 and the gate spacer layers 136 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are made of SiGe and the second semiconductor material layers 106 are made of Si, and the first semiconductor material layers 104 are selectively etched to form the first recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer 149 may be formed in the recess, as shown in FIGS. 1G and 1G-1 in accordance with some embodiments. The inner spacer 149 may provide a barrier between subsequently formed source/drain epitaxial structures and gate structure. The inner spacer 149 may be made of a dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer 149 may be formed using a deposition process. The deposition process may include a CVD process (such as LPCVD, PECVD, SACVD, or FCVD), an ALD process, another applicable method, or a combination thereof.

Next, epitaxial structures 138a1 and 138b1, isolation layers 140, interposing structures 142a and 142b, source/drain epitaxial structures 138a2, 138b2, 138a3, and 138b3 are formed in the source/drain openings 137, as shown in FIGS. 1G and 1G-1 in accordance with some embodiments.. In some embodiments, source/drain epitaxial structures 138a2 and 138a3 may be seen as a first source/drain epitaxial structure 138a. In addition, the epitaxial structures 138a1 and the isolation layer 140 are located under the first source/drain epitaxial structure 138a, and the interposing structures 142a are located beside the first source/drain epitaxial structure 138a in accordance with some embodiments. In some embodiments, the source/drain epitaxial structures 138b2 and 138b3 may be seen as a second source/drain epitaxial structure 138a. In addition, the epitaxial structures 138b1 and the isolation layer 140 are under the second source/drain epitaxial structure 138b, and the interposing structures 142b are located beside the second source/drain epitaxial structure 138b in accordance with some embodiments.

More specifically, the first source/drain epitaxial structure 138a is formed in the source/drain opening 137 in the first region of the substrate 102, as shown in FIG. 1G in accordance with some embodiments. The first source/drain epitaxial structure 138a may be formed in the PMOS region. The second source/drain epitaxial structure 138b is formed in the source/drain opening 137 in the second region of the substrate 102, as shown in FIG. 1G-1 in accordance with some embodiments. The second source/drain epitaxial structure 138b may be formed in the NMOS region. The first source/drain epitaxial structure 138a and the second source/drain epitaxial structure 138b may be referred as source/drain epitaxial structure 138. The source/drain epitaxial structure 138 may be formed over opposite sides of the dummy gate structure 124. The source/drain structure 138 may refer to a source or a drain, individually or collectively dependent upon the context. In some embodiments, the thickness of the source/drain epitaxial structure 138 is different from the width of the source/drain epitaxial structure 138 in a cross-sectional view.

A strained material may be grown in the source/drain opening 137 using an epitaxial (epi) process to form the first source/drain epitaxial structure 138a. In addition, the lattice constant of the strained material may be different from the lattice constant of the substrate 102. The first source/drain epitaxial structure 138a may be in-situ doped during the epitaxial growth process. For example, the first source/drain epitaxial structure 138a may be the epitaxially grown SiGe doped with boron (B). The first source/drain epitaxial structure 138a may be doped in one or more implantation processes after the epitaxial growth process.

The epitaxial structures 138a1 may be made of un-doped or lower doped Si or SiGe. The epitaxial structures 138a1 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or another suitable method.

After the epitaxial structures 138a1 is formed, the isolation layer 140 is formed over the epitaxial structures 138a1, as shown in FIG. 1G in accordance with some embodiments. The isolation layer 140 may provide isolation between the substrate 102 and the subsequently formed source/drain epitaxial structure. The isolation layer 140 may be made of a dielectric material such as SiN, SiO₂, SiON, SiCN, SiCON, SiCO, high-k dielectric material such as HfO, AlO, other suitable dielectric materials, or a combination thereof. The isolation layer 140 may be formed by CVD, PVD, ALD, spin-on coating, or another applicable process.

After the isolation layer 140 is formed, the second semiconductor material layers 106 may be laterally etched from the source/drain opening 137 to form notches. The outer portions of the second semiconductor material layers 106 may be removed, and the inner portions of the second semiconductor material layers 106 under the dummy gate structure 124 and the gate spacer layers 136 may remain. After the lateral etching process, the sidewalls of the etched second semiconductor material layers 106 may be not aligned with the sidewalls of the etched first semiconductor material layers 104. The lateral etching of the second semiconductor material layers 106 may be a dry etching process, a wet etching process, or a combination thereof.

After the second semiconductor material layers 106 are laterally etched to form the notches, first interposing structures 142a may be formed in the notches, as shown in FIG. 1G in accordance with some embodiments. The first interposing structures 142a may be configured to protect the first source/drain epitaxial structure 138a from being damaged during subsequent manufacturing processes. More specifically, after the first source/drain epitaxial structure 138a is formed, the first semiconductor material layers 104 (e.g. SiGe layers) will be removed to form gaps between the second semiconductor material layers 106 by performing an etching process, so that a gate structure may be formed in the gaps to wrap the second semiconductor material layers 106. However, during the etching process, a small amount of the etchant may be infiltrated through the interface between the inner spacers 149 and the second semiconductor material layers 106, and the first source/drain epitaxial structure 138a (e.g. comprising SiGe) may therefore be damaged. Accordingly, by forming the first interposing structures 142a (e.g. with no or low Ge content) at the end of the second semiconductor material layers 106, the leakage of the etchant may be blocked by the first interposing structures 142a during the etching process for removing the first semiconductor material layers 104.

In some embodiments, the first interposing structures 142a and the first semiconductor material layers 104 are made of different materials. In some embodiments, the first interposing structures 142a and the first source/drain epitaxial structure 138ahave different compositions. In some embodiments, the first interposing structures 142a includes SiB. In some embodiments, the first interposing structures 142a is free of Ge. In some embodiments, the first interposing structures 142a further includes Ge, and the Ge concentration in the first protection structures 142a is less than 5%. If the Ge concentration of the first interposing structures 142a is too high, the etching rate of the first interposing structures 142a may not be able to stop the etchant during the etching process for removing the first semiconductor material layers 104, and the subsequently formed epitaxial structure may therefore be damaged.

In some embodiments, the etching rate of the first interposing structures 142a is different from the etching rate of the first semiconductor material layers 104 during the etching process for removing the first semiconductor material layers 104 in the following processes. In some embodiments, the etching rate of the first interposing structures 142a is lower than the etching rate of the first semiconductor material layers 104 during the etching process for removing the first semiconductor material layers 104 in the following processes. Since the etching rates are different, the first interposing structures 142a may not be etched when removing the first semiconductor material layers 104 in the subsequently gate forming process. Therefore, the subsequently formed first source/drain epitaxial structure 138a may not be etched when removing the first semiconductor material layers 104 in the gate structure forming process. The first interposing structures 142a may prevent the first source/drain epitaxial structures 138a from being damaged when forming the gate structure. Therefore, the leakage between the subsequently formed gate structure and contacts may be reduced.

The first interposing structures 142a may be a protection structure. The first interposing structures 142a may be an epitaxial layer. The first interposing structures 142a may be formed by an epitaxial growth step, such as MOCVD, MOVPE, PECVD, RP-CVD, MBE, HVPE, LPE, Cl-VPE, or another suitable method.

In some embodiments, the first interposing structures 142a cover at least a portion of the sidewalls of the inner spacers 149. In some embodiments, the first interposing structures 142a vertically protrude from the top surfaces and the bottom surfaces of the second semiconductor material layers 106 by a distance of D. In some embodiments, the distance D is greater than 1 nm. If the distance D is too short, the subsequently formed epitaxial structure may be damaged when forming the subsequently formed gate structure.

Since the first interposing structures 142a are filled in the notches, the first interposing structures 142a has an extending portion 142ae sandwiched between the inner spacers 149. In some embodiments, the first interposing structures 142a cover at least a portion of the top surface of the inner spacers 149.

Next, a source/drain epitaxial structures 138a2 of the first source/drain epitaxial structure 138a is formed over the first interposing structures 142a and the isolation layer 140, as shown in FIG. 1G in accordance with some embodiments. The source/drain epitaxial structures 138a2 of the first source/drain epitaxial structure 138a may include SiGeB, SiGe, other applicable materials, or a combination thereof. The source/drain epitaxial structures 138a2 of the first source/drain epitaxial structure 138a may be doped SiGeB. In some embodiments, the dopant concentration of the source/drain epitaxial structures 138a2 of the first source/drain epitaxial structure 138a is higher than the dopant concentration of the epitaxial structures 138a1. Therefore, dopant out-diffusing issue may be prevented. The source/drain epitaxial structures 138a2 of the first source/drain epitaxial structure 138a may be formed by an epitaxial growth step, such as MOCVD, MOVPE, PECVD, RP-CVD, MBE, HVPE, LPE, Cl-VPE, or any other suitable method. In some embodiments, the source/drain epitaxial structures 138a2 of the first source/drain epitaxial structure 138a interfacing the first interposing structures 142a.

Later, a source/drain epitaxial structures 138a3 of the first source/drain epitaxial structure 138a is formed over the source/drain epitaxial structures 138a2 of the first source/drain epitaxial structure 138a in the source/drain opening 137, as shown in FIG. 1G in accordance with some embodiments. In some embodiments, the source/drain epitaxial structures 138a3 of the first source/drain epitaxial structure 138a of the first source/drain epitaxial structure 138a is separated from the interposing structure 142 by the source/drain epitaxial structures 138a2 of the first source/drain epitaxial structure 138a.

The source/drain epitaxial structures 138a3 of the first source/drain epitaxial structure 138a may include SiGeB, SiGe, other applicable materials, or a combination thereof. The source/drain epitaxial structures 138a3 of the first source/drain epitaxial structure 138a may be doped SiGeB. In some embodiments, the dopant concentration of the source/drain epitaxial structures 138a3 of the first source/drain epitaxial structure 138a is different from the dopant concentration of the source/drain epitaxial structures 138a2 of the first source/drain epitaxial structure 138a. In some embodiments, the dopant concentration of the source/drain epitaxial structures 138a3 of the first source/drain epitaxial structure 138a is higher than the dopant concentration of the source/drain epitaxial structures 138a2 of the first source/drain epitaxial structure 138a. Therefore, dopant out-diffusing issue may be prevented.

In some embodiment, the Ge concentration of the source/drain epitaxial structures 138a2 of the first source/drain epitaxial structure 138a and the source/drain epitaxial structures 138a3 of the first source/drain epitaxial structure 138a is in a range of about 20% to about 70%. The source/drain epitaxial structures 138a3 of the first source/drain epitaxial structure 138a may be formed by an epitaxial growth step, such as MOCVD, MOVPE, PECVD, RP-CVD, MBE, HVPE, LPE, Cl-VPE, or any other suitable method.

It should be noted that, the number of the layers of the first source/drain epitaxial structure 138a is merely an example, the first source/drain epitaxial structure 138a may have more layers with different Ge concentration, depending on the process demands.

A first gap 144a may be formed between the isolation layer 140 and the first source/drain epitaxial structure 138a, including the source/drain epitaxial structures 138a2 of the first source/drain epitaxial structure 138a and the source/drain epitaxial structures 138a3 of the first source/drain epitaxial structure 138a, as shown in FIG. 1G in accordance with some embodiments.

The second source/drain epitaxial structure 138b may include SiP, SiAs, other applicable materials, or a combination thereof. The second source/drain epitaxial structure 138b may be phosphorous to form silicon: phosphor (Si:P) source/drain features, epitaxially grown Si doped with carbon to form silicon: carbon (Si:C) source/drain features, or both carbon and phosphorous to form silicon carbon phosphor (SiCP) source/drain features.

The second source/drain epitaxial structure 138b may include epitaxial structures 138b1 formed at the bottom of the source/drain opening 137, as shown in FIG. 1G-1 in accordance with some embodiments. The epitaxial structures 138b1 may be made of un-doped or lower doped Si or SiGe.

After forming the epitaxial structures 138b1 at the bottom of the source/drain opening 137, the isolation layer 140 is formed over the epitaxial structures 138b1, as shown in FIG. 1G-1 in accordance with some embodiments.

Later, the second interposing structures 142b are formed in the notches. In some embodiments, the second interposing structures 142b and the second epitaxial source/drain epitaxial structure 138b are made of different materials. In some embodiments, the second interposing structures 142b and the first interposing structures 142a are made of different materials. In some embodiments, the second interposing structures 142b includes SiAs or SiCP, or a combination thereof. In some embodiments, the As concentration of the SiAs in the second interposing structures 142b is in a range of about 0.5% to about 10%. In some embodiments, the C concentration of the SiCP in the second interposing structures 142b is in a range of about 0.2% to about 1%. The second interposing structures 142b may prevent dopant diffusion from the subsequently formed second source/drain epitaxial structure 138b. Therefore, the drain induced barrier lowering (DIBL) leakage may be improved. More specifically, since the second interposing structures 142b vertically protrude from the nanostructures 106, the leakage at the edge of the second interposing structures 142b may also be prevented. In some embodiments, the diffusion length of dopants of the second source/drain epitaxial structure 138b in the second interposing structures 142b and the diffusion length of dopants of the second source/drain epitaxial structure 138b in the second source/drain epitaxial structure 138b are different.

The second interposing structures 142b has an extending portion 142be sandwiched between the inner spacers 149. In some embodiments, the extending portion 142be of the second interposing structures 142b has a width of Wb, and the extending portion 142ae of the first interposing structures 142a has a width of Wa, as shown in FIGS. 1G and 1G-1 in accordance with some embodiments. In some embodiments, the width Wb of the extending portion 142be of the second interposing structures 142b is less than the Wa of the extending portion 142ae of the first interposing structures 142a. In some embodiments, the amount of the first interposing structures 142a that extend between the inner spacers 149 is more than the amount that the second interposing structures 142b extend between the inner spacers 149.

The first interposing structures 142a and the second interposing structures 142b may be referred as the interposing structures 142 formed between the second semiconductor material layers 106 and the source/drain epitaxial structures 138.

Later, the source/drain epitaxial structures 138b2 of the second source/drain epitaxial structure 138b is formed over the second interposing structures 142b and the isolation layer 140, and the source/drain epitaxial structures 138b3 of the second source/drain epitaxial structure 138b is formed over the source/drain epitaxial structures 138b2 of the second source/drain epitaxial structure 138b in the source/drain opening 137, as shown in FIG. 1G-1 in accordance with some embodiments. In some embodiments, the dopant concentration of the source/drain epitaxial structures 138b3 of the second source/drain epitaxial structure 138b is higher than the dopant concentration of the source/drain epitaxial structures 138b2 of the second source/drain epitaxial structure 138b. Therefore, dopant out-diffusing issue may be prevented.

In some embodiment, the P concentration of the source/drain epitaxial structures 138b2 of the second source/drain epitaxial structure 138b and the source/drain epitaxial structures 138b3 of the second source/drain epitaxial structure 138b is in a range of about 5E20 to about 5E21.

It should be noted that, the number of the layers of the second source/drain epitaxial structure 138b is merely an example, the second source/drain epitaxial structure 138b may have more layers with different P concentrations, depending on the process demands.

A second gap 144b may be formed between the source/drain epitaxial structures 138b2 of the second source/drain epitaxial structure 138b and the source/drain epitaxial structures 138b3 of the second source/drain epitaxial structure 138b over the isolation layer 140, as shown in FIG. 1G-1 in accordance with some embodiments. In some embodiments, the first gap 144a is smaller than the second gap 144b.

The processes for forming the second source/drain epitaxial structure 138b may be the same as, or similar to, those used to form the first source/drain epitaxial structure 138a. For the purpose of brevity, the descriptions of these processes are not repeated herein.

The process sequence of forming the first source/drain epitaxial structure 138a and the second source/drain epitaxial structure 138b is not limited. The first source/drain epitaxial structure 138a may be formed before the second source/drain epitaxial structure 138b, or the first source/drain epitaxial structure 138a may be formed after the second source/drain epitaxial structure 138b, depending on the process demands. For the purpose of brevity, only the first source/drain epitaxial structure 138a is shown in the following embodiments, but the second source/drain epitaxial structure 138b may also be applied.

Next, an etch stop layer 146 may be formed over the source/drain epitaxial structure 138, as shown in FIG. 1H in accordance with some embodiments. More specifically, the etch stop layer 146 may cover the sidewalls of the gate spacer layers 136 and the top surface of the first source/drain epitaxial structure 138a. The etch stop layer 146 may be made of a dielectric material such as silicon nitride, silicon oxide, silicon oxynitride (SiON), other applicable materials, or a combination thereof. The etch stop layer 146 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The etch stop layer 146 may be a bi-layer structure. For example, the etch stop layer 146 may be made of silicon oxynitride (SiON) and silicon nitride. With a bi-layer etch stop layer 146, the capacitance may be reduced.

After the etch stop layer 146 is formed, an inter-layer dielectric (ILD) structure 148 is formed over the etch stop layer 146 and the first source/drain epitaxial structure 138a, as shown in FIG. 1H in accordance with some embodiments. In some embodiments, the ILD structure 148 surrounds the source/drain epitaxial structure 138.

The ILD structure 148 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 148 may be formed by chemical vapor deposition (CVD), physical vapor deposition (PVD), atomic layer deposition (ALD), spin-on coating, or another applicable process.

Afterwards, a planarizing process or an etch-back process may be performed on the ILD structure 148 until the top surface of the dummy gate structure 124 is exposed. After the planarizing process, the top surface of the dummy gate structure 124 may be substantially level with the top surfaces of the gate spacer layers 136 and the ILD structure 148. The planarizing process may include a grinding process, a chemical mechanical polishing (CMP) process, an etching process, other applicable processes, or a combination thereof.

Next, the first semiconductor material layers 104 may be removed and gaps may be formed between the second semiconductor material layers 106. More specifically, the second semiconductor material layers 106 exposed by the gaps form nanostructures 106, and the nanostructures 106 are configured to function as channel regions 106 in the resulting semiconductor devices 10a in accordance with some embodiments.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), potassium hydroxide (KOH) solutions, or a combination thereof.

Next, gate structures 150 are formed surrounding the nanostructures 106 and over the nanostructures 106, as shown in FIG. 1H in accordance with some embodiments. Gate structures 150 are formed surrounding the nanostructures 106 to form gate-all-around (GAA) transistor structures. Therefore, the gate control ability may be enhanced.

In some embodiments as shown in FIG. 1H, the gate structures 150 are multi-layered structures. Each of the gate structures 150 may include an interfacial layer, a gate dielectric layer 150a, a work function layer 150b, and a gate electrode layer.

The interfacial layer may be formed around the nanostructures 106 and on the exposed portions of the base fin structures. The interfacial layer may be made of silicon oxide, and the interfacial layer may be formed by thermal oxidation.

The gate dielectric layer 150a may be formed over the interfacial layer, so that the nanostructures 106 are surrounded (e.g. wrapped) by the gate dielectric layer 150a. In addition, the gate dielectric layer 150a also covers the sidewalls of the gate spacer layers 136 and the inner spacers 149 in accordance with some embodiments. The gate dielectric layer 150a may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, other applicable high-k dielectric materials, or a combination thereof. The gate dielectric layer 150a may be formed using CVD, ALD, other applicable methods, or a combination thereof. In some embodiments, the dielectric constant of the gate dielectric layer 150a is greater than the dielectric constant of the gate spacer layer 136.

Next, the work function layer 150b is conformally formed over the gate dielectric layer 150a, as shown in FIG. 1H in accordance with some embodiments. The work function layer 150b may be made of a metal material. The metal material of the work function layer 150b formed in the first region in the substrate 102 may include a P-work-function metal. The P-work-function metal may include titanium nitride (TiN), tungsten nitride (WN), tantalum nitride (TaN), ruthenium (Ru), or a combination thereof. The metal material of the work function layer 150b formed in the second region in the substrate 102 may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The work function layer 150b may be formed using CVD, ALD, other applicable methods, or a combination thereof.

Next, a gate electrode layer may be formed over the work function layer 150b The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer comprises titanium-containing material. The gate electrode layer may be formed using CVD, ALD, electroplating, another applicable method, or a combination thereof. After the gate electrode layer is formed, a planarization process such as CMP or an etch-back process may be performed.

Next, an opening may be formed in the ILD structure 148. A barrier layer may be conformally formed over the bottom surface and the sidewalls of the opening. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Next, a silicide structure may be formed in the source/drain epitaxial structure 138. The silicide structure may reduce the contact resistance between the source/drain epitaxial structure 138 and the subsequently formed contact structure over the source/drain epitaxial structure 138.

The silicide structure may be made of TiSi, Ti₅Si₄, TiSi₂, NiSi, NiSi₂, CoSi, CoSi₂, WSi₂ and MoSi₂, or other suitable low-resistance materials. The silicide structure may be formed over the source/drain epitaxial structure 138 by forming a metal layer over the source/drain epitaxial structure 138 first. The metal layer may react with the source/drain epitaxial structure 138 in an annealing process and a silicide layer may be produced. Afterwards, the unreacted metal layer may be removed in an etching process and the silicide structure may be formed over the source/drain epitaxial structure 138.

Afterwards, a contact structure 152 is formed into the opening over the source/drain epitaxial structure 138, as shown in FIGS. 1I and 1I-1 in accordance with some embodiments. The contact structure 152 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The contact structure 152 may be formed by a CVD process, a PVD process, an ALD, an electroplating process, another suitable process, or a combination thereof to deposit the conductive materials of the contact structure 152, and then a planarization process such as a chemical mechanical polishing (CMP) process or an etch back process is optionally performed to remove excess conductive materials. After the planarization process, the top surface of the contact structure 152 may be level with the top surface of the gate spacer layer 136.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing.

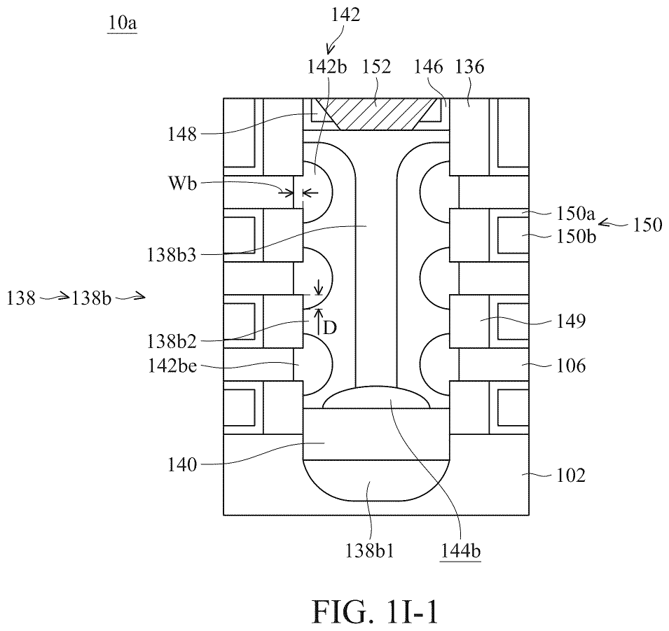

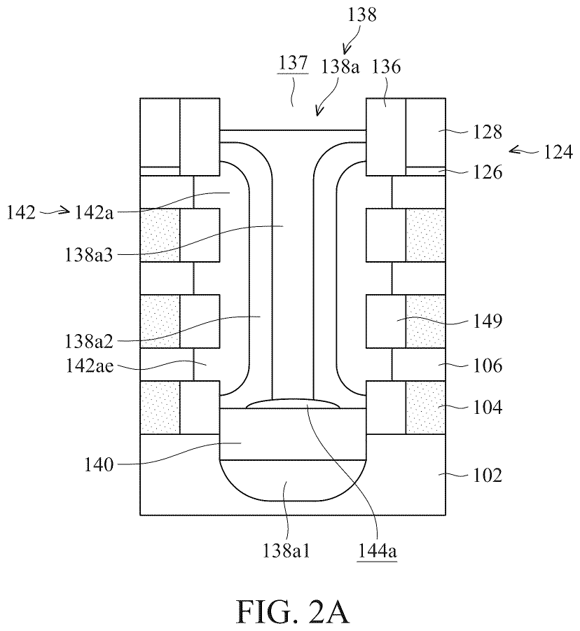

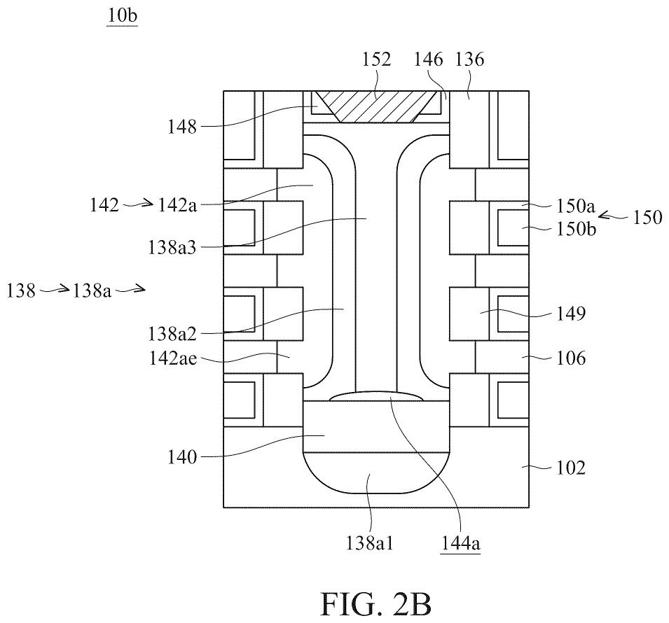

Many variations and/or modifications may be made to the embodiments of the disclosure. FIGS. 2A-2B, 3A, 3A-1, 3B, 3B-1 and 4A-4B are cross-sectional representations of various stages of forming a semiconductor device structure 10b, 10c and 10d, respectively. Some processes or devices are the same as, or similar to, those described in the embodiments above, and therefore the descriptions of these processes and devices are not repeated herein. The difference from the embodiments described above is that, as shown in FIG. 2A in accordance with some embodiments, adjacent interposing structures 142 are merged.

The interposing structures 142 may be formed by repeated deposition and etching process. If the process time is longer, adjacent interposing structures 142 may be merged. In some embodiments, the sidewalls of the inner spacers are covered by the interposing structures 142. In some embodiments, the source/drain epitaxial structures 138a2 of the first source/drain epitaxial structure 138a and the inner spacers 149 are separated by the interposing structures 142. In some embodiments, at least a portion of the interposing structures 142 are merged. The merged interposing structures 142 may further prevent the leakage between the gate structure 150 and the contacts 152.

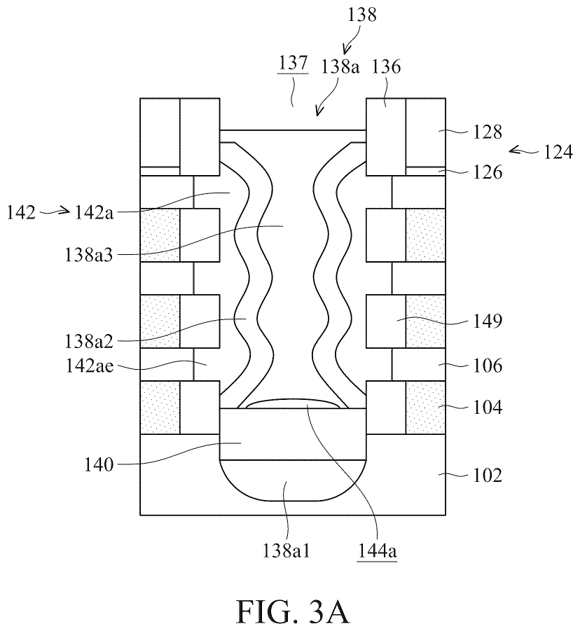

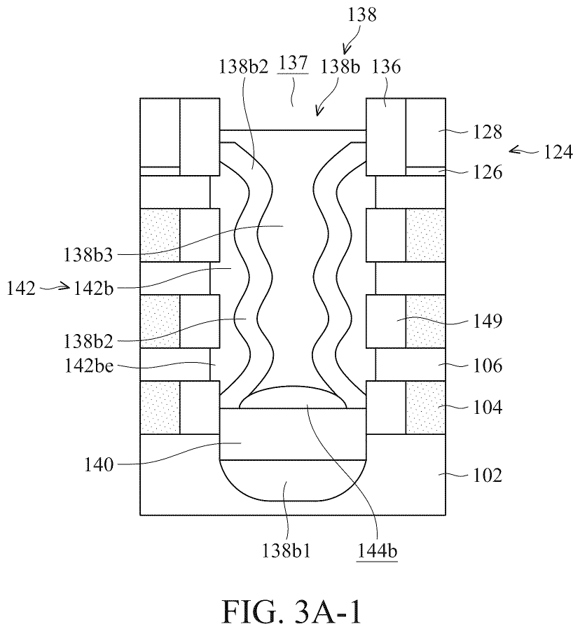

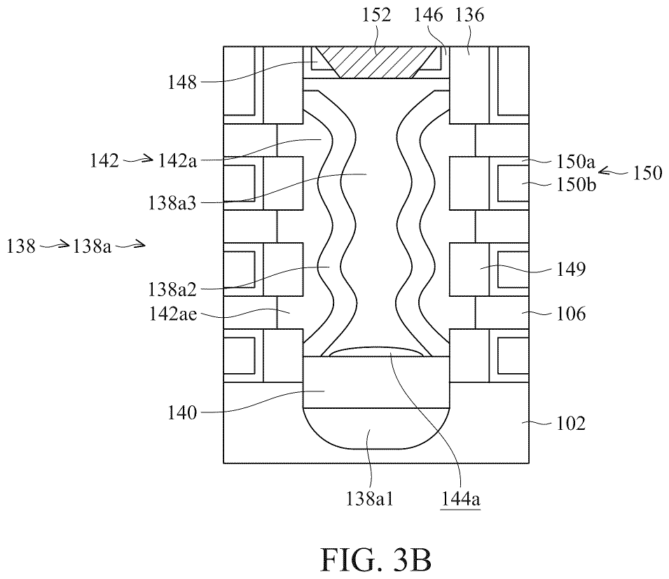

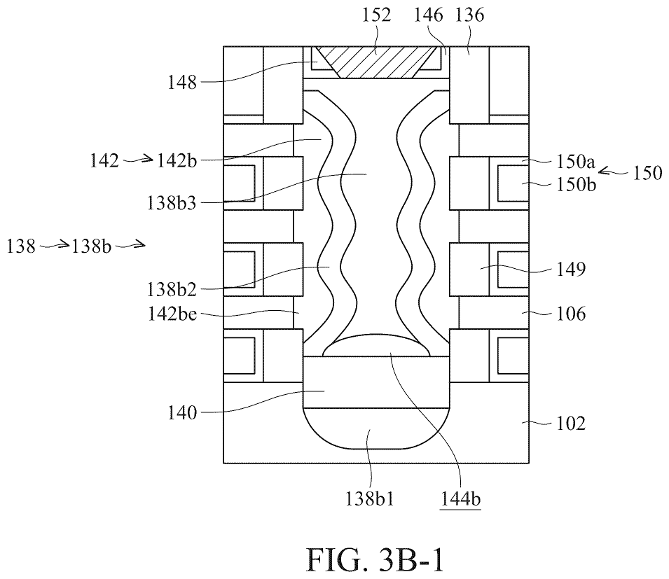

When adjacent interposing structures 142 are merged, the sidewalls of the interposing structures 142 are wavy, as shown in FIGS. 3A and 3A-1 in accordance with some embodiments. The source/drain epitaxial structures 138a2 of the first source/drain epitaxial structure 138a and the source/drain epitaxial structures 138b2 of the second source/drain epitaxial structure 138b may be conformally formed over the sidewall of the merged interposing structures 142. Therefore, the sidewalls of the source/drain epitaxial structures 138a2 of the first source/drain epitaxial structure 138a and the source/drain epitaxial structures 138b2 of the second source/drain epitaxial structure 138b are wavy, too. In some embodiments, since the first gap 144a is smaller than the second gap 144b. The source/drain epitaxial structures 138a3 of the first source/drain epitaxial structure 138a is in direct contact with the isolation layer 140, and the source/drain epitaxial structures 138b3 of the second source/drain epitaxial structure 138b is separated from the isolation layer 140. With merged second interposing structures 142b, the DIBL leakage may further reduced.

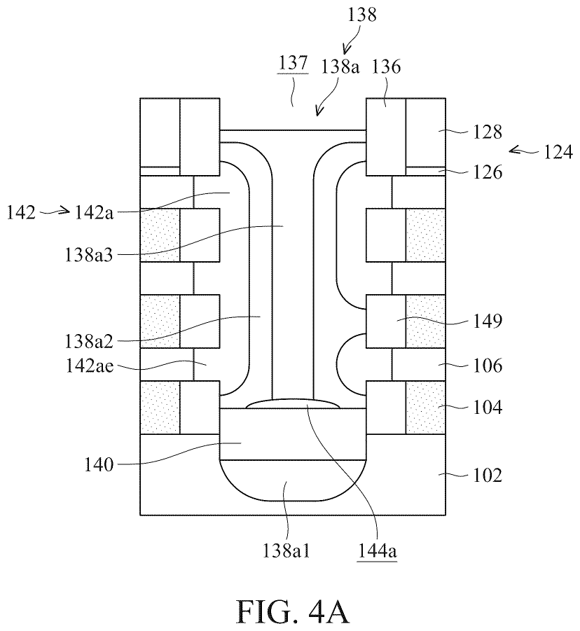

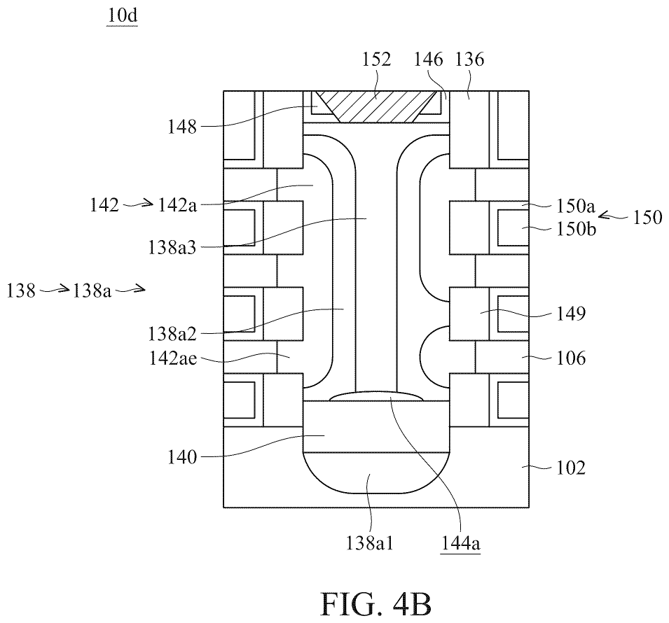

The adjacent interposing structures 142 are randomly merged, as shown in FIG. 4A in accordance with some embodiments. In some embodiments, some of the adjacent interposing structures 142 are merged, and some of the adjacent interposing structures 142 are separated.

It should be noted that, the number and the position of merged interposing structures 142 and the separated interposing structures 142 is merely an example, and the embodiments is not limited thereto. The number and the position of the merged interposing structures 142 and the separated interposing structures 142 may be randomly distributed.

Later, the gate structure 150 are formed, and the contact structure 152 are formed over the source/drain epitaxial structures 138, as shown in FIGS. 2B, 3B, 3B-1 and 4B in accordance with some embodiments. The processes for forming the gate structure 150 and the contact structure 152 may be the same as, or similar to, those used to form the gate structure 150 and the contact structure 152 in the previous embodiments. For the purpose of brevity, the descriptions of these processes are not repeated herein.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. Adjacent interposing structures 142 may be randomly merged, and the sidewalls of the merged interposing structures 142 may be wavy.

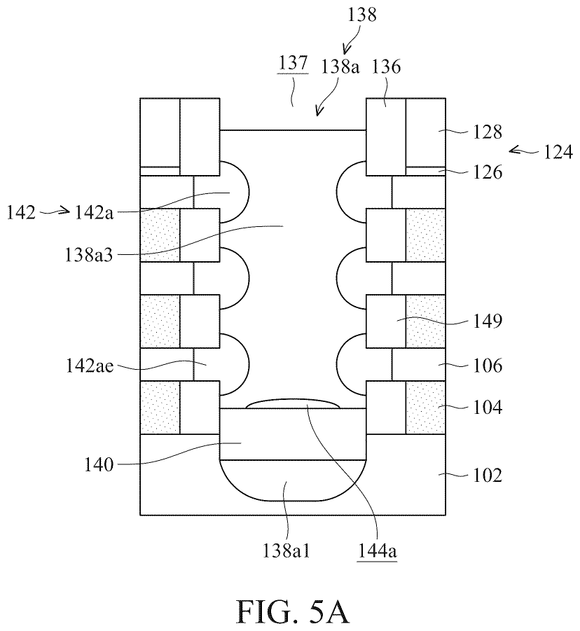

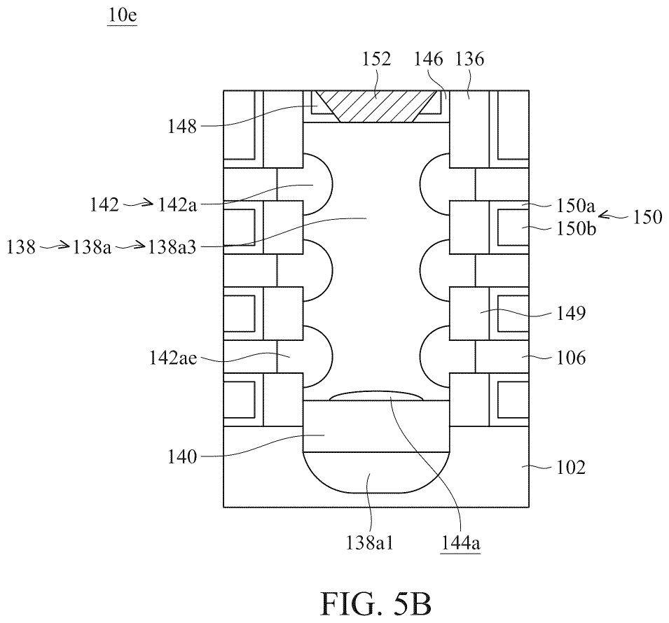

Many variations and/or modifications may be made to the embodiments of the disclosure. FIGS. 5A-5B, 6A-6B and 7A-7B are cross-sectional representations of various stages of forming a semiconductor device structure 10e, 10f and 10g, respectively. Some processes or devices are the same as, or similar to, those described in the embodiments above, and therefore the descriptions of these processes and devices are not repeated herein. The difference from the embodiments described above is that, as shown in FIG. 5A in accordance with some embodiments, the source/drain epitaxial structures 138a3 of the first source/drain epitaxial structure 138a is formed over the interposing structures 142.

Since the interposing structures 142 are vertically protruding from the nanostructures 106, the dopant in the source/drain epitaxial structure 138 may not be out-diffused. Therefore, the source/drain epitaxial structures 138a3 of the first source/drain epitaxial structure 138a with a higher dopant concentration may be formed directly over the interposing structures 142. Since the volume of the source/drain epitaxial structures 138a3 of the first source/drain epitaxial structure 138a is increased, the performance of the semiconductor device structure 10e may be enhanced.

In some embodiments, the source/drain epitaxial structures 138a3 of the first source/drain epitaxial structure 138a is in direct contact with the interposing structures 142. In some embodiments, the source/drain epitaxial structures 138a3 of the first source/drain epitaxial structure 138a is in direct contact with the inner spacers 149.

The source/drain epitaxial structures 138a3 of the first source/drain epitaxial structure 138a may have a constant Ge concentration or a gradient Ge concentration, and the source/drain epitaxial structures 138b3 of the second source/drain epitaxial structure 138b may have a constant P concentration or a gradient P concentration (not shown), depending on the process demands.

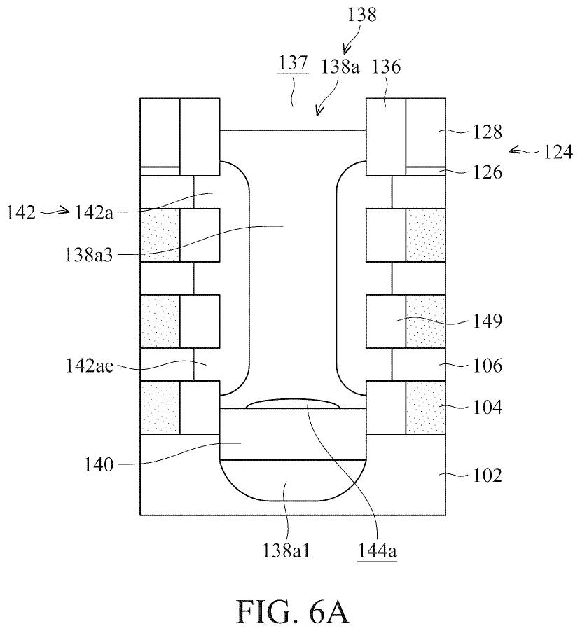

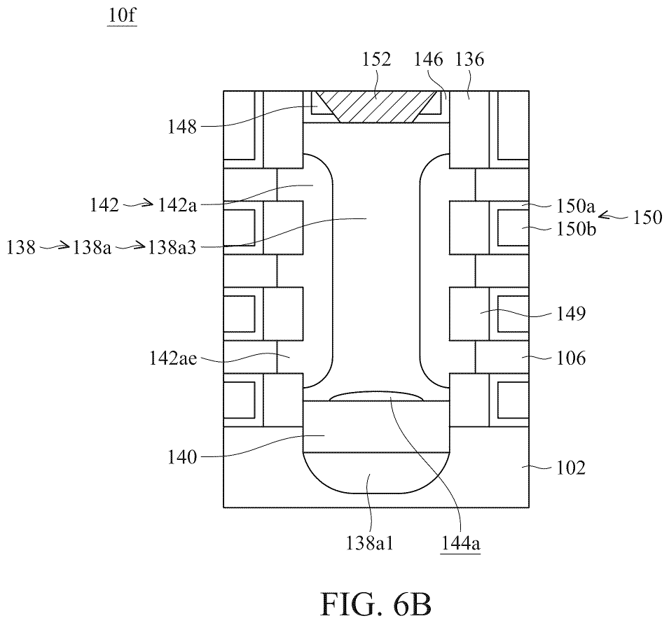

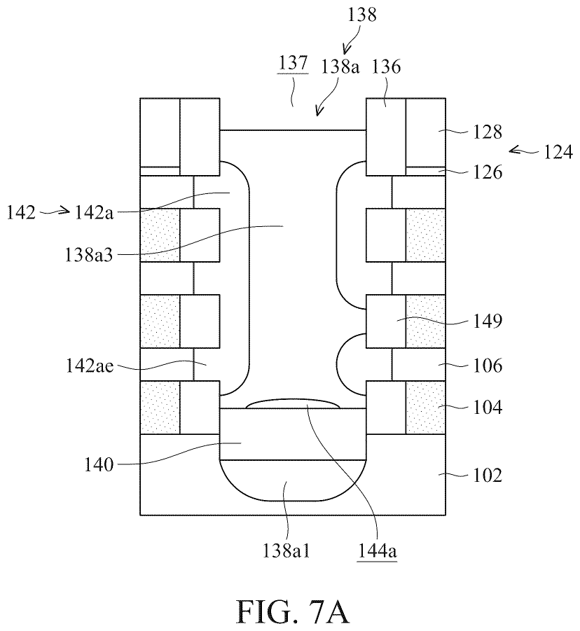

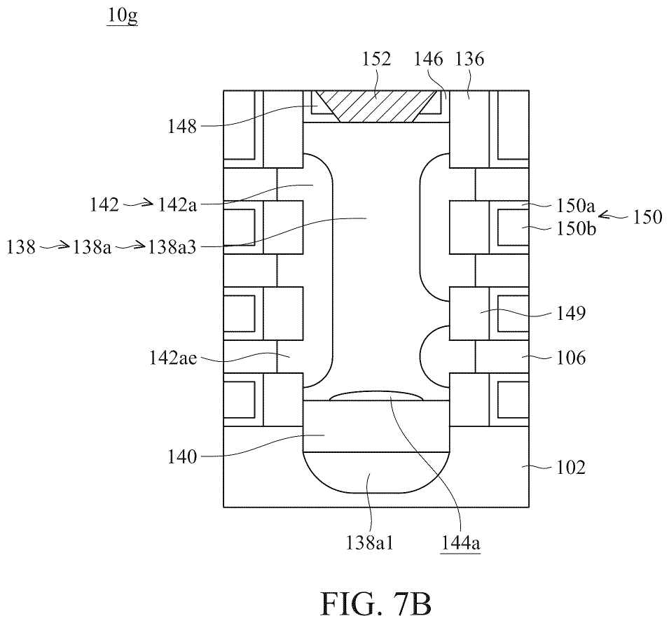

With the source/drain epitaxial structures 138a3 of the first source/drain epitaxial structure 138a directly formed over the interposing structures 142, the interposing structures 142 are merged during repeated deposition and etching processes, as shown in FIGS. 6A-6B in accordance with some embodiments. The interposing structures 142 are randomly merged, as shown in FIGS. 7A-7B in accordance with some embodiments. The position of the merged interposing structures 142 are not limited. The processes and materials for forming the interposing structures 142 may be the same as, or similar to, those used to form the interposing structures 142 in the previous embodiments. For the purpose of brevity, the descriptions of these processes are not repeated herein.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The source/drain epitaxial structures 138a3 of the source/drain epitaxial structure 138 may be directly formed over the interposing structures 142, and the device performance may be enhanced.

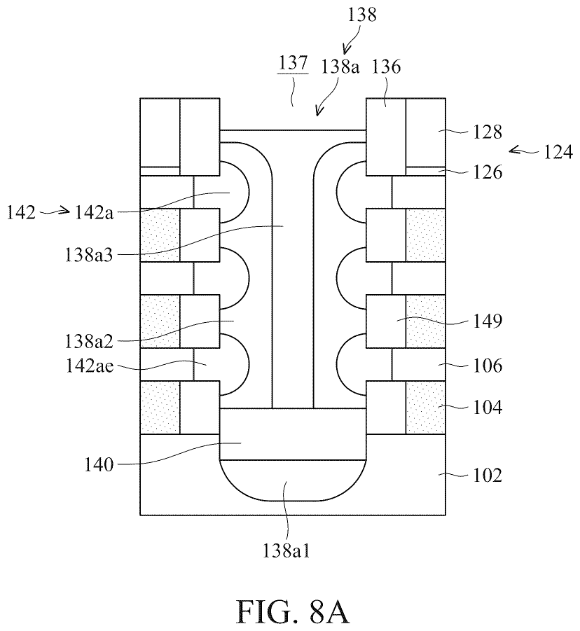

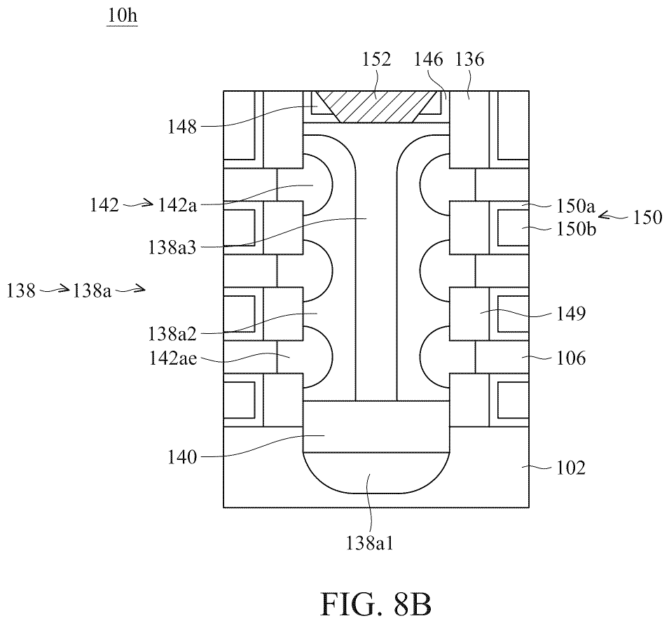

Many variations and/or modifications may be made to the embodiments of the disclosure. FIGS. 8A-8B are cross-sectional representations of various stages of forming a semiconductor device structure 10h. Some processes or devices are the same as, or similar to, those described in the embodiments above, and therefore the descriptions of these processes and devices are not repeated herein. The difference from the embodiments described above is that, as shown in FIG. 8A in accordance with some embodiments, there is no gap between the source/drain epitaxial structures 138 and the isolation layer 140.

The source/drain epitaxial structures 138 may be filled at the bottom of the source/drain opening 137 without forming a gap. In some embodiments, both of the source/drain epitaxial structures 138a2 of the first source/drain epitaxial structure 138a and the source/drain epitaxial structures 138a3 of the first source/drain epitaxial structure 138a are in direct contact with the isolation layer 140. The enlarged source/drain epitaxial structures 138 may enhance device performance.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. There may be no gap between the source/drain epitaxial structures 138 and the isolation layer 140, and the device performance may be enhanced.

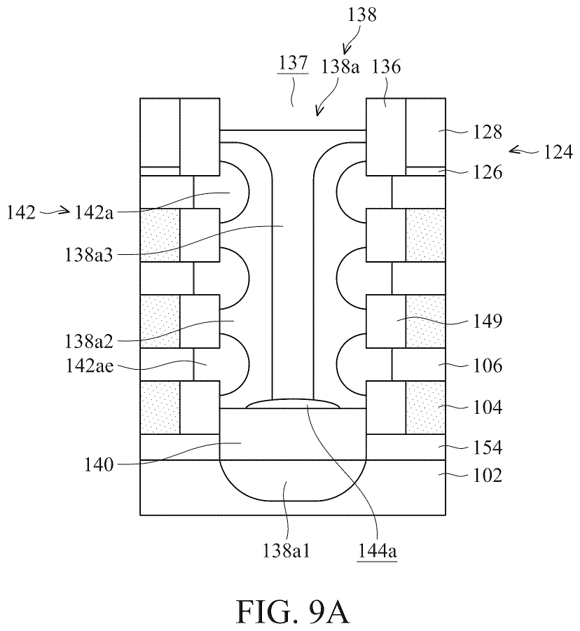

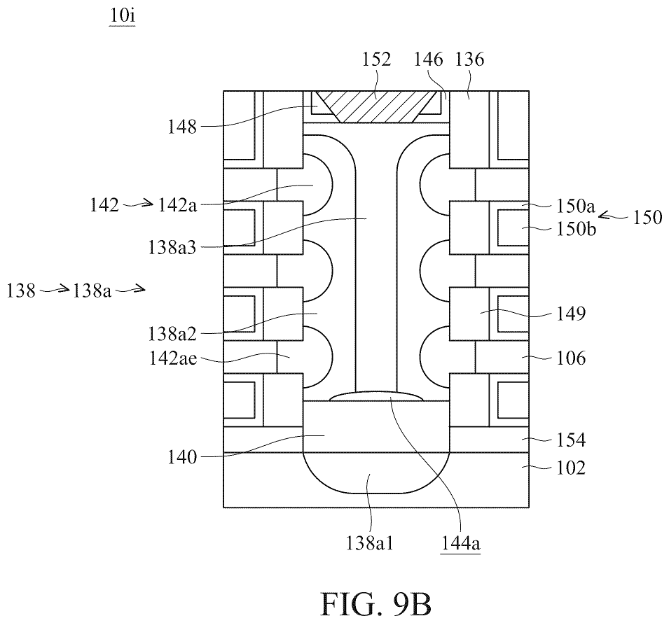

Many variations and/or modifications may be made to the embodiments of the disclosure. FIGS. 9A-9B are cross-sectional representations of various stages of forming a semiconductor device structure 10i. Some processes or devices are the same as, or similar to, those described in the embodiments above, and therefore the descriptions of these processes and devices are not repeated herein. The difference from the embodiments described above is that, as shown in FIG. 9A in accordance with some embodiments, a gate isolation layer 154 is formed between the first semiconductor material layers 104 and the substrate 102.

Before forming the semiconductor stack 108, a gate isolation layer 154 is deposited over the substrate 102. Later, the first semiconductor material layers 104 of the semiconductor stack 108 is deposited thereon. The gate isolation layer 154 may be made of SiN, SiO₂, SiON, SiCN, SiCON, SiCO, high-k dielectric material such as HfO, AlO, other suitable dielectric materials, or a combination thereof. The gate isolation layer 154 may be a multi-layer structure. The gate isolation layer 154 may be formed using CVD, ALD, other applicable methods, or a combination thereof. The gate isolation layer 154 may prevent substrate leakage current.

A portion of the gate isolation layer 154 are removed when forming the source/drain opening 137 and the source/drain structure 138 is formed in the source/drain opening 137, as shown in FIG. 9A in accordance with some embodiments.

Later, the gate structure 150 are formed, as shown in FIG. 9B in accordance with some embodiments. The processes for forming the gate structure 150 may be the same as, or similar to, those used to form the gate structure 150 in the previous embodiments. For the purpose of brevity, the descriptions of these processes are not repeated herein. In some embodiments, the gate isolation layer 154 is formed between the substrate 102 and a bottommost surface of the gate structure 150.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The gate isolation layer 154 formed between the substrate 102 and the gate structure 150 may prevent substrate leakage current.

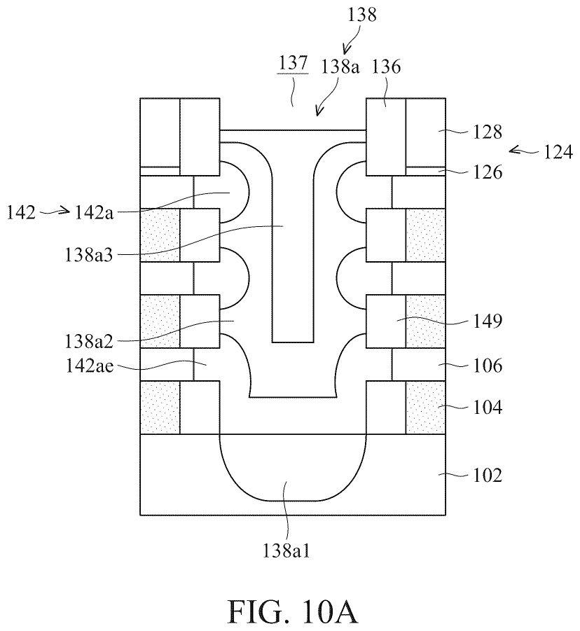

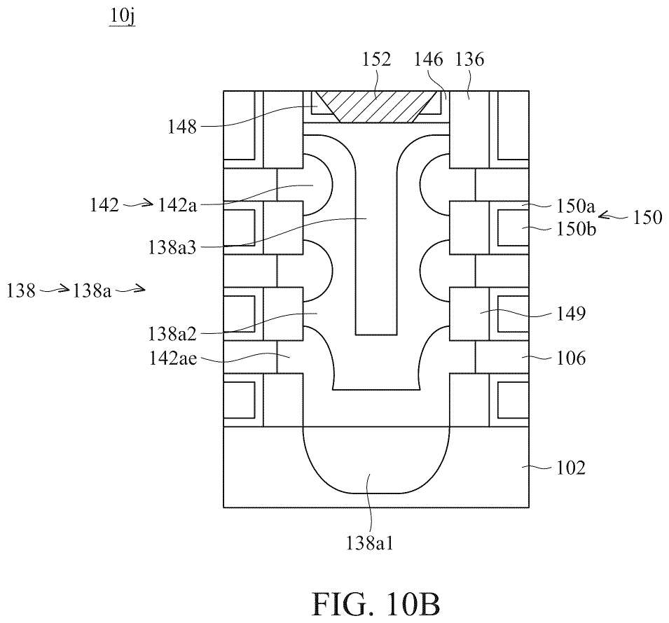

Many variations and/or modifications may be made to the embodiments of the disclosure. FIGS. 10A-10B, 11A-11B, 12A-12B and 13A-13B are cross-sectional representations of various stages of forming a semiconductor device structure 10j, 10k, 10l and 10m, respectively. Some processes or devices are the same as, or similar to, those described in the embodiments above, and therefore the descriptions of these processes and devices are not repeated herein. The difference from the embodiments described above is that, as shown in FIG. 10A in accordance with some embodiments, the interposing structure 142 is grown over the epitaxial structure 138a1.

Without forming the isolation layer 140, the interposing structure 142 may be in direct contact with the epitaxial structure 138a1, as shown in FIGS. 10A-10B in accordance with some embodiments. In some embodiments, the interposing structures 142 formed over the sidewalls of the bottommost nanostructures 106 are merged with the interposing structures 142 over the epitaxial structure 138a1.

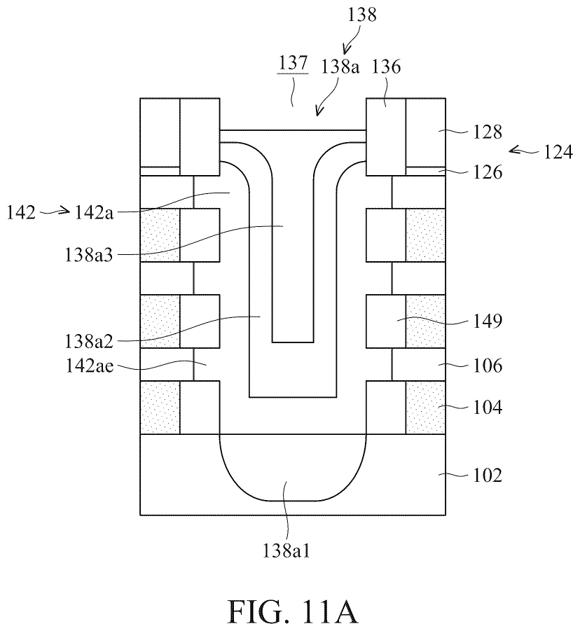

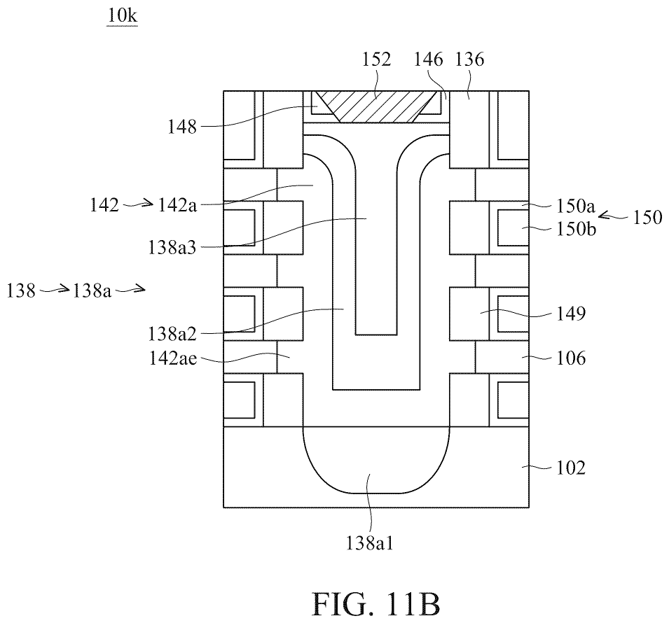

With the interposing structure 142 directly formed over the epitaxial structure 138a1, the interposing structures 142 are merged during repeated deposition and etching processes, as shown in FIGS. 11A-11B in accordance with some embodiments.

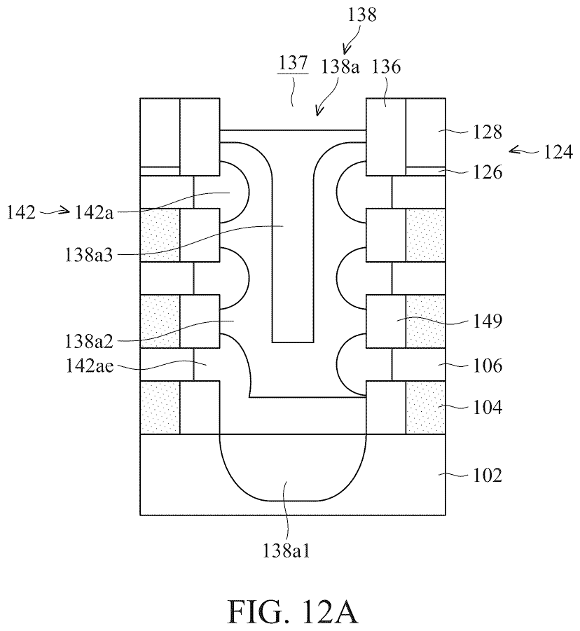

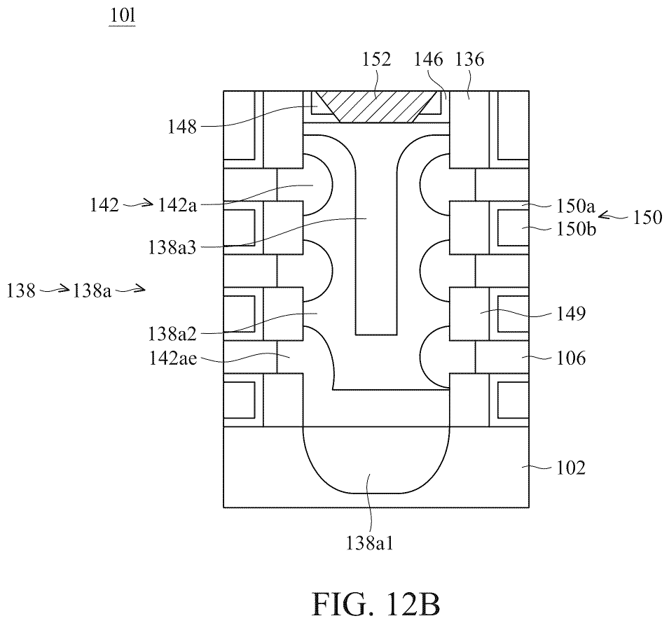

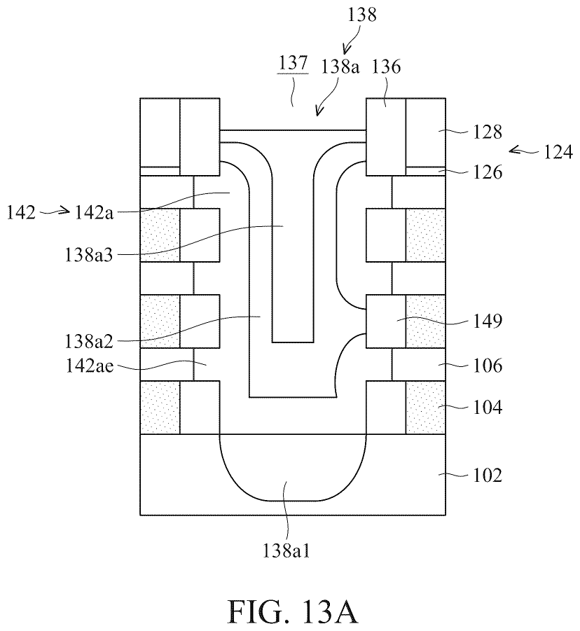

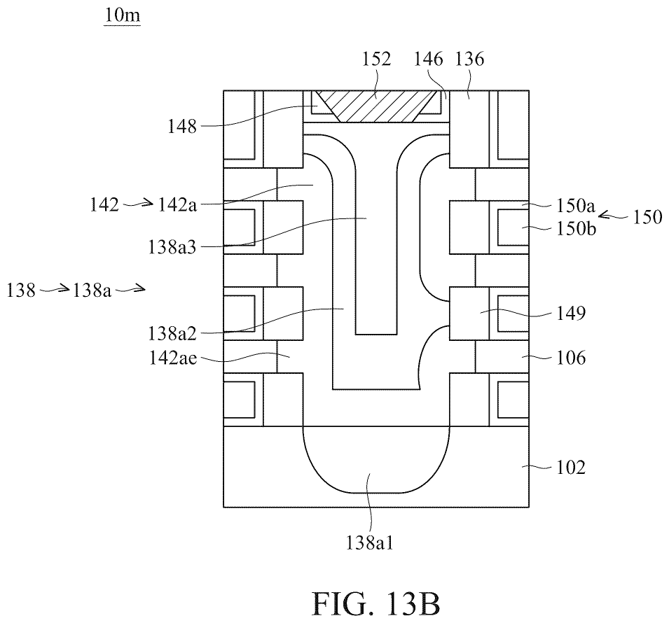

The interposing structures 142 are randomly merged, as shown in FIGS. 12A-12B and 13A-13B in accordance with some embodiments. Only one side of the interposing structures 142 formed over the sidewalls of the bottommost nanostructures 106 are merged with the interposing structures over the source/drain epitaxial structure 138a1, as shown in FIGS. 12A-12B in accordance with some embodiments. Both sides of the interposing structures 142 formed over the sidewalls of the bottommost nanostructures 106 are merged with the interposing structures over the epitaxial structure 138a1, as shown in FIGS. 13A-13B in accordance with some embodiments. The position of the merged interposing structures 142 are not limited. The processes and materials for forming the interposing structures 142 may be the same as, or similar to, those used to form the interposing structures 142 in the previous embodiments. For the purpose of brevity, the descriptions of these processes are not repeated herein.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The interposing structures 142 may be formed over the epitaxial structure 138a1 directly, and at least one of the interposing structures 142 formed over the sidewalls of the bottommost nanostructures 106 may be merged with the interposing structures 142 over the epitaxial structure 138a1.

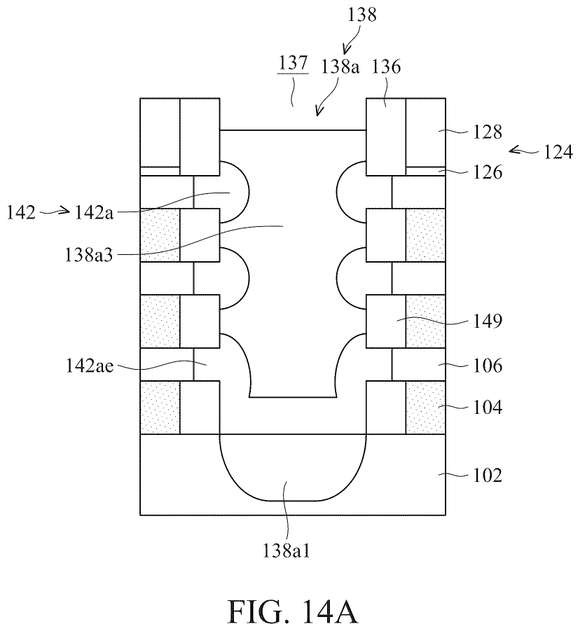

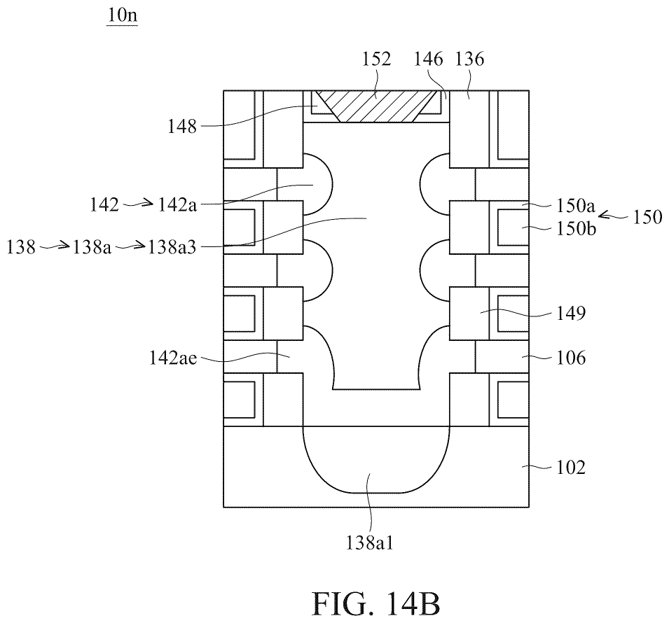

Many variations and/or modifications may be made to the embodiments of the disclosure. FIGS. 14A-14B, 15A-15B, 16A-16B and 17A-17B are cross-sectional representations of various stages of forming a semiconductor device structure 10n, 10o, 10p and 10q, respectively. Some processes or devices are the same as, or similar to, those described in the embodiments above, and therefore the descriptions of these processes and devices are not repeated herein. The difference from the embodiments described above is that, as shown in FIG. 14A in accordance with some embodiments, the interposing structure 142 is formed over the epitaxial structure 138a1 and the source/drain epitaxial structures 138a3 of the source/drain epitaxial structure 138 is formed over the interposing structures 142.

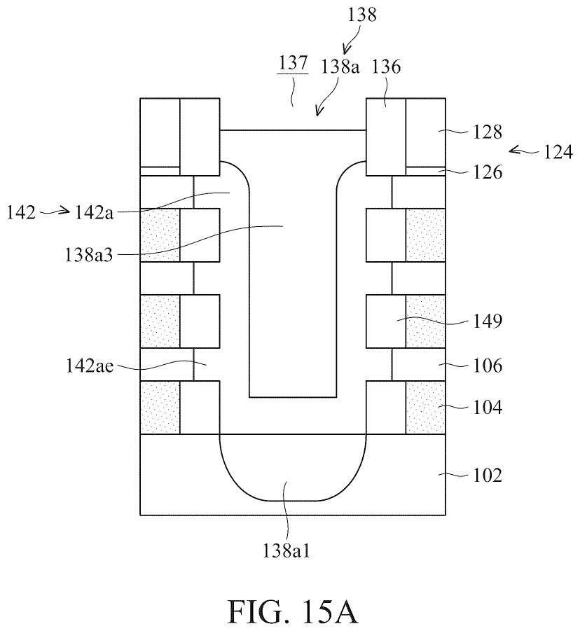

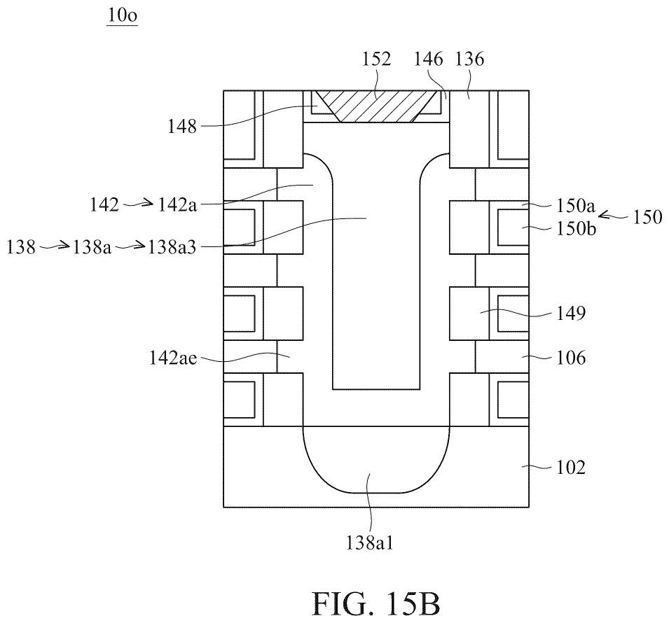

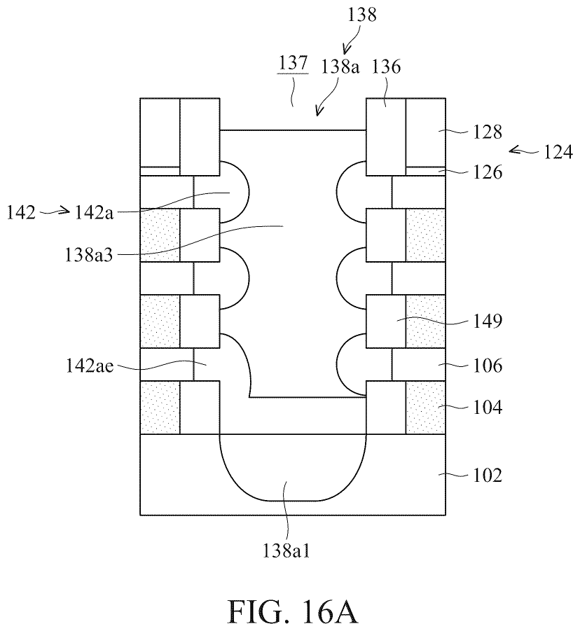

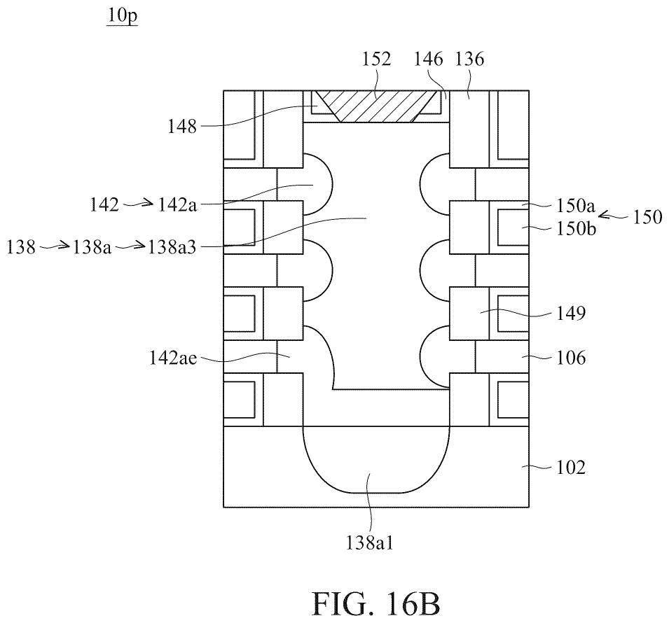

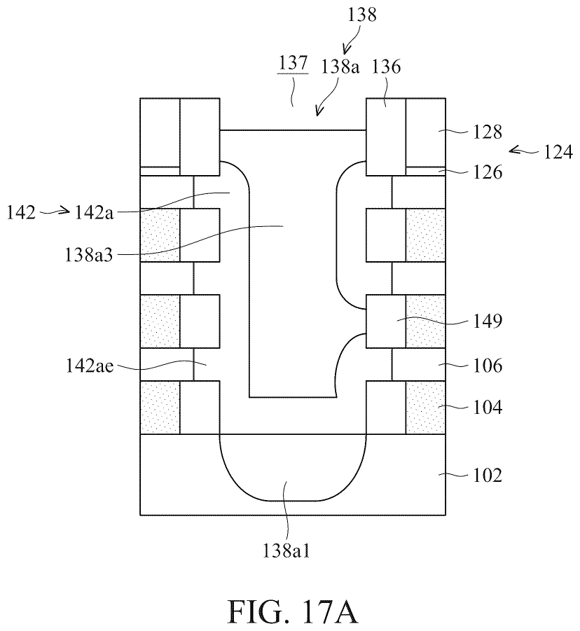

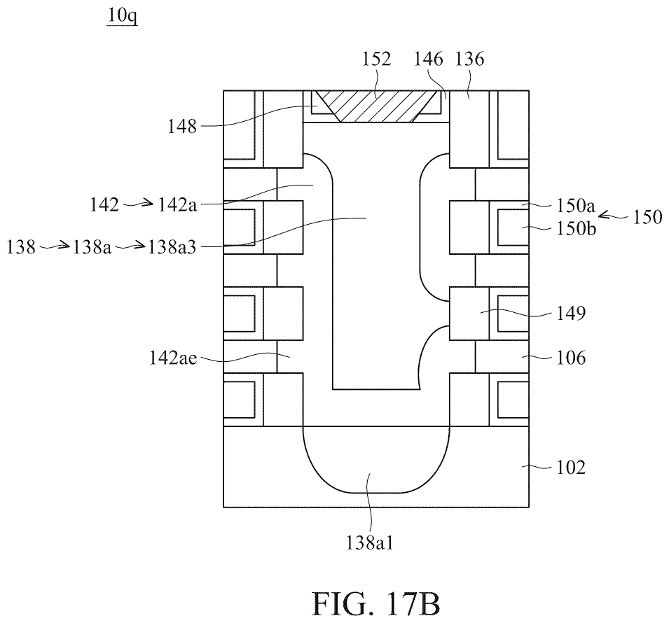

With the source/drain epitaxial structures 138a3 of the source/drain epitaxial structure 138 directly formed over the interposing structures 142, the interposing structures 142 formed over both sidewalls of the bottommost nanostructures 106 may be merged with the interposing structures 142 over the epitaxial structure 138a1, as shown in FIGS. 14A-14B in accordance with some embodiments. The interposing structures 142 are merged during repeated deposition and etching processes, as shown in FIGS. 15A-15B in accordance with some embodiments. The interposing structures 142 are randomly merged, as shown in FIGS. 16A-16B and 17A-17B in accordance with some embodiments. The position of the merged interposing structures 142 are not limited. At least one of the interposing structures 142 formed over the sidewalls of the bottommost nanostructures 106 may be merged with the interposing structures 142 over the epitaxial structure 138a1.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The source/drain epitaxial structures 138a3 of the source/drain epitaxial structure 138 may be directly formed over the interposing structures 142, and the device performance may be enhanced. The interposing structures 142 may be formed over the epitaxial structure 138a1 directly, and at least one of the interposing structures 142 formed over the sidewalls of the bottommost nanostructures 106 may be merged with the interposing structures 142 over the epitaxial structure 138a1.

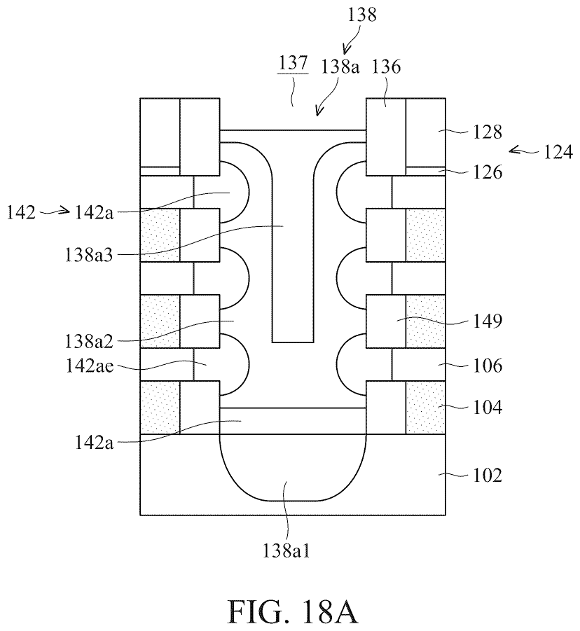

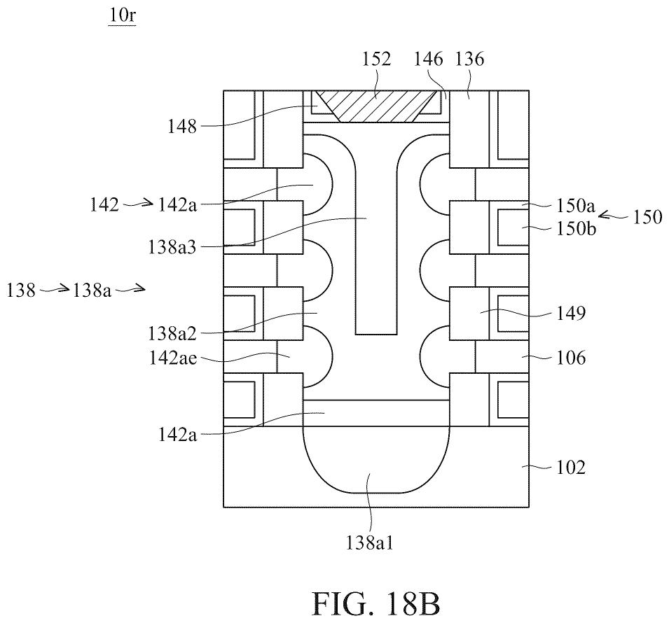

Many variations and/or modifications may be made to the embodiments of the disclosure. FIGS. 18A-18B are cross-sectional representations of various stages of forming a semiconductor device structure 10r. Some processes or devices are the same as, or similar to, those described in the embodiments above, and therefore the descriptions of these processes and devices are not repeated herein. The difference from the embodiments described above is that, as shown in FIG. 18A in accordance with some embodiments, the interposing structures 142 formed over the sidewalls of the bottommost nanostructures 106 may be separated from the interposing structures 142 over the source/drain epitaxial structure 138a1.

The interposing structures 142 formed over the epitaxial structure 138a1 and the interposing structures 142 beside the nanostructures 106 are separated from each other, as shown in FIGS. 18A-18B in accordance with some embodiments.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The interposing structures 142 may be formed over the epitaxial structure 138a1 directly, and the interposing structures 142 are separated from each other.

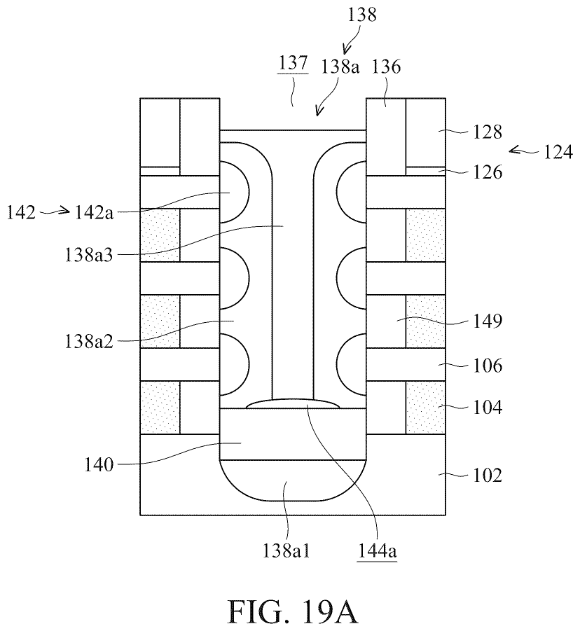

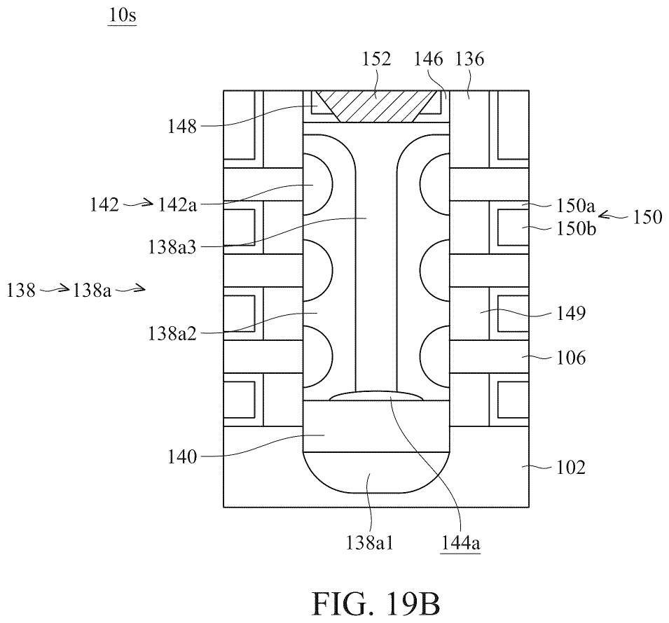

Many variations and/or modifications may be made to the embodiments of the disclosure. FIGS. 19A-19B are cross-sectional representations of various stages of forming a semiconductor device structure 10s. Some processes or devices are the same as, or similar to, those described in the embodiments above, and therefore the descriptions of these processes and devices are not repeated herein. The difference from the embodiments described above is that, as shown in FIG. 19A in accordance with some embodiments, the interposing structures 142 do not extend between the inner spacers 149.

In some embodiment, the second semiconductor material layers 106 are not recessed before forming the interposing structures 142, as shown in FIG. 19A in accordance with some embodiments. Therefore, the sidewalls of the interposing structures 142 may be substantially aligned with the sidewalls of the inner spacers 149.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The nanostructures 106 may not be laterally recessed, and the interposing structures 142 does not extend between the inner spacers 149.

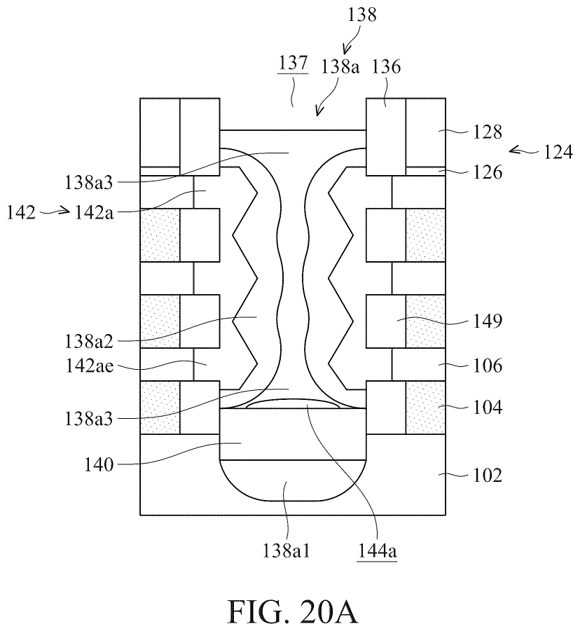

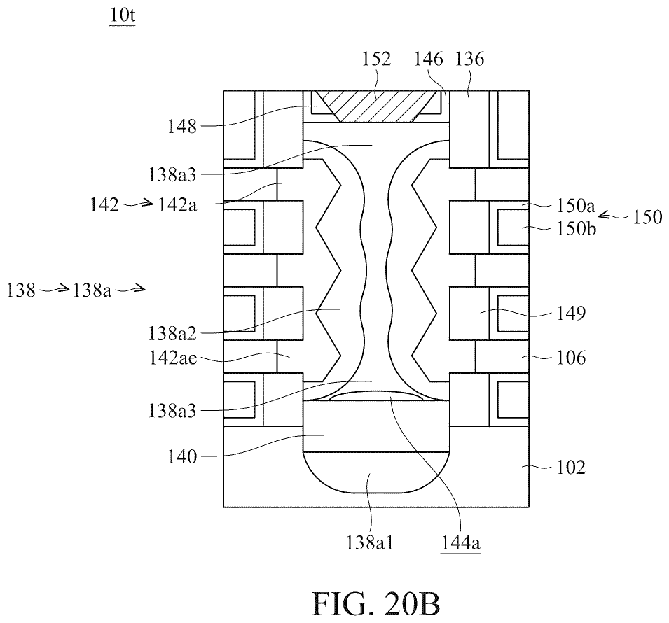

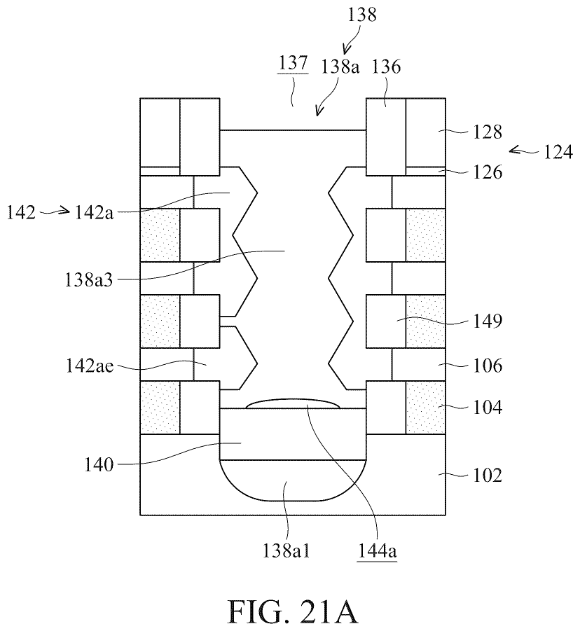

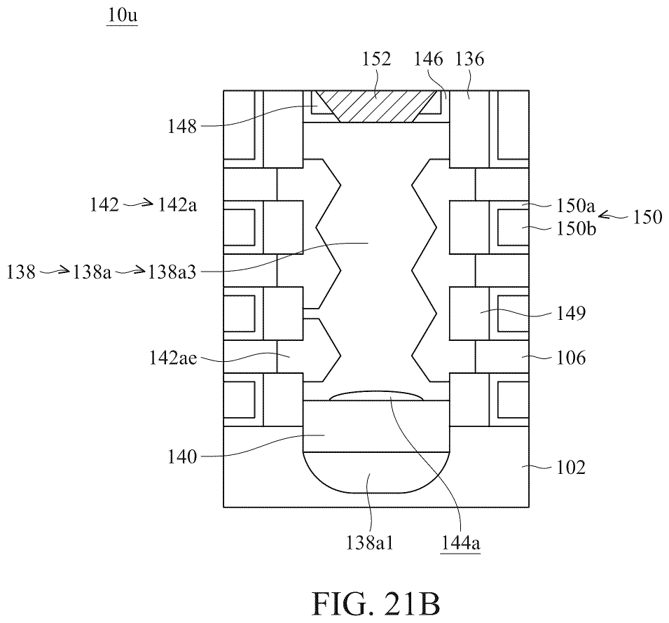

Many variations and/or modifications may be made to the embodiments of the disclosure. FIGS. 20A-20B and 21A-21B are cross-sectional representations of various stages of forming a semiconductor device structure 10t and 10u, respectively. Some processes or devices are the same as, or similar to, those described in the embodiments above, and therefore the descriptions of these processes and devices are not repeated herein. The difference from the embodiments described above is that, as shown in FIG. 20A in accordance with some embodiments, the interposing structures 142 have angled corners.

With interposing structures 142 have angled corners, the sidewalls of the source/drain epitaxial structures 138a2 of the first source/drain epitaxial structure 138a may be wavy since the source/drain epitaxial structures 138a2 of the first source/drain epitaxial structure 138a is conformally formed over the interposing structures 142. The interposing structures 142 are be merged, as shown in FIGS. 20A-20B in accordance with some embodiments.

The source/drain epitaxial structures 138a3 of the first source/drain epitaxial structure 138a directly formed over the interposing structures 142, and the interposing structures 142 are randomly merged, as shown in FIGS. 21A-21B in accordance with some embodiments. The position of the merged interposing structures 142 are not limited. The processes and materials for forming the interposing structures 142 may be the same as, or similar to, those used to form the interposing structures 142 in the previous embodiments. For the purpose of brevity, the descriptions of these processes are not repeated herein.

By forming the interposing structures 142 made of different material from the source/drain epitaxial structures 138 and covering at least a portion of the sidewalls of the inner spacers 149, the first interposing structures 142a may prevent the first source/drain epitaxial structure 138a from being damaged and the leakage current may be reduced. The second interposing structure 142b may prevent the dopant in the second source/drain epitaxial structure 138b from diffusing. The interposing structures 142 may have angled corners.

It should be noted that, although the embodiments shown in FIGS. 2A-2B, 4A-4B, 5A-5B, 6A-6B, 7A-7B, 8A-8B, 9A-9B, 10A-10B, 11A-11B, 12A-12B, 13A-13B, 14A-14B, 15A-15B, 16A-16B, 17A-17B, 18A-18B, 19A-19B, 20A-20B and 21A-21B only the first interposing structures 142a are shown, these embodiments are not limited thereto. These embodiments may be applied to the second interposing structures 142b.

As described previously, the interposing structures 142 and the source/drain epitaxial structures 138 have different compositions, and the interposing structures 142 covers at least a portion of the sidewall the inner spacer 149. In some embodiments as shown in FIGS. 2A-2B, the interposing structures 142 may be merged. In some embodiments as shown in FIGS. 3A, 3A-1, 3B and 3B-1, the sidewalls of the interposing structures 142 are wavy. In some embodiments as shown in FIGS. 4A-4B, the interposing structures 142 are merged randomly. In some embodiments as shown in FIGS. 5A-5B, 6A-6B, 7A-7B, the source/drain epitaxial structures 138a3 of the source/drain epitaxial structures 138 is in direct contact with the interposing structures 142. In some embodiments as shown in FIGS. 8A-8B, there is no gap between the source/drain epitaxial structures 138 and the isolation layer 140. In some embodiments as shown in FIGS. 9A-9B, a gate isolation layer 154 is formed between the substrate 102 and the gate structure 150. In some embodiments as shown in FIGS. 10A-10B, 11A-11B, 12A-12B, 13A-13B, the interposing structure 142 is directly formed over the epitaxial structures 138a1. In some embodiments as shown in FIGS. 14A-14B, 15A-15B, 16A-16B, 17A-17B, the interposing structure 142 is directly formed over the epitaxial structures 138a1, and the source/drain epitaxial structures 138a3 of the source/drain epitaxial structures 138 is in direct contact with the interposing structures 142. In some embodiments as shown in FIGS. 18A-18B, the interposing structure 142 is directly formed over the epitaxial structures 138a1, and the interposing structures 142 are separated from each other. In some embodiments as shown in FIGS. 19A-19B, the interposing structures 142 does not extend between the inner spacers 149. In some embodiments as shown in FIGS. 20A-20B and 21A-21B, the interposing structures 142 have angled corners.

Embodiments of a semiconductor device structure and a method for forming the same are provided. Interposing structures with different material from the source/drain epitaxial structures may be formed between the nanostructures and the source/drain epitaxial structures. The interposing structures may vertically extend over the nanostructures. The source/drain epitaxial structures may not be damaged when forming the gates, and the dopant in the source/drain epitaxial structures may not be out-diffused.

In some embodiments, a semiconductor device structure is provided. The semiconductor device structure includes nanostructures formed over a substrate. The semiconductor device structure also includes a gate structure wrapped around the nanostructures. The gate structure includes a gate dielectric layer and a gate electrode over the gate dielectric layer. The gate electrode comprises a titanium-containing material. The semiconductor device structure also includes inner spacers formed over opposite sides of the gate structure. Each of the inner spacers includes a top surface, a bottom surface, and a sidewall connecting the top surface and the bottom surface. The semiconductor device structure also includes interposing structures formed over sidewalls of the nanostructures. The semiconductor device structure also includes a source/drain epitaxial structure formed over the interposing structures. A thickness of the source/drain epitaxial structure is different from a width of the source/drain epitaxial structure in a cross-sectional view. The interposing structures and the source/drain epitaxial structures have different compositions, and the interposing structure covers the sidewall of at least one of the inner spacers.

In some embodiments, a semiconductor device structure is provided. The semiconductor device structure includes first nanostructures formed over a first region of a substrate. The semiconductor device structure also includes a first gate structure comprising a first gate dielectric layer over the first nanostructure and a gate electrode over the first gate dielectric layer. The semiconductor device structure also includes a first gate spacer extending along a sidewall of the first gate structure. A dielectric constant of the first gate dielectric layer is greater than a dielectric constant of the first gate spacer. The semiconductor device structure also includes first inner spacers formed beside the first gate structure. The semiconductor device structure also includes first interposing structures interfacing sidewalls of the first nanostructure. The semiconductor device structure also includes first source/drain epitaxial structures surrounding the first interposing structures. The semiconductor device structure also includes an etch stop layer over the first source/drain epitaxial structures. The semiconductor device structure also includes a dielectric layer over the etch stop layer. The first interposing structures comprise SiB, and the first interposing structures vertically protruding from top surfaces of the first nanostructures and bottom surfaces of the first nanostructures.

In some embodiments, a method for forming a semiconductor device structure is provided. The method for forming a semiconductor device structure includes forming a fin structure including channel layers and sacrificial layers alternately stacked over a substrate. The method for forming a semiconductor device structure also includes forming inner spacers between the channel layers. The method for forming a semiconductor device structure also includes recessing the channel layers to form notches between the inner spacers. The method for forming a semiconductor device structure also includes growing interposing structures in the notches and vertically extending outside the notches. The interposing structures are made of a first semiconductor material with a first Ge concentration of lower than 5%. The method for forming a semiconductor device structure also includes forming source/drain epitaxial structures surrounding the interposing structures. The method for forming a semiconductor device structure also includes removing the sacrificial layers by performing a first etching process to form openings between the channel layers. The method for forming a semiconductor device structure also includes forming a gate structure in the openings. Etching rates of the interposing structures and the sacrificial layers in the first etching process are different.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. Semiconductor device structure, comprising:
nanostructures formed over a substrate;
a gate structure wrapped around the nanostructures, wherein the gate structure comprises a gate dielectric layer and a gate electrode over the gate dielectric layer, wherein the gate electrode comprises a titanium-containing material;
inner spacers formed over opposite sides of the gate structure, wherein each of the inner spacers comprises a top surface, a bottom surface, and a sidewall connecting the top surface and the bottom surface;
interposing structures formed over sidewalls of the nanostructures; and
a source/drain epitaxial structure formed over the interposing structures, wherein a thickness of the source/drain epitaxial structure is different from a width of the source/drain epitaxial structure in a cross-sectional view;
wherein the interposing structures and the source/drain epitaxial structure have different compositions, and the interposing structures cover the sidewall of at least one of the inner spacers.

2. The semiconductor device structure as claimed in claim 1, wherein the interposing structures cover at least a portion of the top surfaces the inner spacers.

3. The semiconductor device structure as claimed in claim 1, wherein at least a portion of the interposing structures are merged.

4. The semiconductor device structure as claimed in claim 3, wherein sidewalls of the interposing structures are wavy.

5. The semiconductor device structure as claimed in claim 1, further comprising;
an isolation layer formed under the source/drain epitaxial structure.

6. The semiconductor device structure as claimed in claim 5, further comprising;
a gap between the isolation layer and the source/drain epitaxial structure.

7. A semiconductor device structure, comprising:
first nanostructures formed over a first region of a substrate;
a first gate structure comprising a first gate dielectric layer over the first nanostructure and a gate electrode over the first gate dielectric layer;
a first gate spacer extending along a sidewall of the first gate structure, wherein a dielectric constant of the first gate dielectric layer is greater than a dielectric constant of the first gate spacer;
first interposing structures interfacing sidewalls of the first nanostructures;
first source/drain epitaxial structures surrounding the first interposing structures;
an etch stop layer over the first source/drain epitaxial structures; and
a dielectric layer over the etch stop layer,
wherein the first interposing structures comprise SiB, and the first interposing structures vertically protrude from top surfaces of the first nanostructures and bottom surfaces of the first nanostructures.

8. The semiconductor device structure as claimed in claim 7, wherein the first source/drain epitaxial structures comprise:
a first layer in direct contact with the first interposing structures; and
a second layer spaced away from the first interposing structures by the first layer,
wherein dopant concentrations of the first layer and the second layer are different.

9. The semiconductor device structure as claimed in claim 7, wherein a concentration of Ge in the first interposing structures is lower than 5%, and a concentration of Ge in the first source/drain epitaxial structures is greater than 20%.

10. The semiconductor device structure as claimed in claim 7, further comprising:
second nanostructures formed over a second region of the substrate;
a second gate structure over the second nanostructures;
second inner spacers formed beside the second gate structure;
second interposing structures interfacing sidewalls of the second nanostructures; and
second source/drain epitaxial structures surrounding the second interposing structures,
wherein the first interposing structures and the second interposing structures are made of different materials.

11. The semiconductor device structure as claimed in claim 10, wherein the second interposing structures comprise SiAs, SiCP, or a combination thereof.

12. The semiconductor device structure as claimed in claim 10, further comprising:
first inner spacers formed beside the first gate structure,
wherein an amount that the first interposing structures extend between the first inner spacers is more than an amount that the second interposing structures extend between the second inner spacers.

13. The semiconductor device structure as claimed in claim 10, further comprising:
a bottom layer formed under the first source/drain epitaxial structures and the second source/drain epitaxial structures; and
an isolation structure formed over the bottom layer,
wherein a first gap is between the isolation structure and the first source/drain epitaxial structures, a second gap is between the isolation structure and the second source/drain epitaxial structures, and the first gap is smaller than the second gap.

14. The semiconductor device structure as claimed in claim 7, further comprising:
a gate isolation structure formed between the substrate and a bottommost surface of the first gate structure.

15. A method for forming a semiconductor device structure, comprising:
forming a fin structure comprising channel layers and sacrificial layers alternately stacked over a substrate;
forming inner spacers between the channel layers;
recessing the channel layers to form notches between the inner spacers;
growing interposing structures in the notches and vertically extending outside the notches, wherein the interposing structures are made of a first semiconductor material with a first Ge concentration of lower than 5%;
forming source/drain epitaxial structures surrounding the interposing structures;
removing the sacrificial layers by performing a first etching process to form openings between the channel layers; and
forming a gate structure in the openings,
wherein etching rates of the interposing structures and the sacrificial layers in the first etching process are different.

16. The method for forming the semiconductor device structure as claimed in claim 15, wherein diffusion lengths of dopants of the source/drain epitaxial structures in the interposing structures and in the source/drain epitaxial structures are different.

17. The method for forming the semiconductor device structure as claimed in claim 15, wherein the source/drain epitaxial structures comprise a first layer and a second layer, wherein the first layer is interfacing the interposing structures and the second layer spaced apart from the interposing structures by the first layer.

18. The method for forming the semiconductor device structure as claimed in claim 15, wherein forming the source/drain epitaxial structures comprises:
forming a bottom layer over the substrate before growing the interposing structures,
wherein the interposing structures are grown over the bottom layer.

19. The method for forming the semiconductor device structure as claimed in claim 18, wherein a first one of the interposing structures over the bottom layer is separated from a second one of the interposing structures beside the channel layers.

20. The method for forming the semiconductor device structure as claimed in claim 15, wherein the interposing structures have angled corners.
